(19) United States
(12) Patent Application Publication
(10) Pub. No.: US 2006/0055089 A1
(43) Pub. Date: Mar. 16, 2006

(54) Zoned radiation crosslinked elastomeric materials

(76) Inventors: John J. Zhang, Cincinnati, OH (US); Matthew G. McNally, West Chester, OH (US); Thomas H. Daugherty, Cincinnati, OH (US)

Correspondence Address: THE PROCTER & GAMBLE COMPANY;INTELLECTUAL PROPERTY DIVISION, WINTON HILL TECHNICAL CENTER - BOX 161, 6110 CENTER HILL AVENUE, CINCINNATI, OH, 45224, US

(21) Appl. No.: 11/253,502

(22) Filed: Oct. 19, 2005

Related U.S. Application Data
(63) Continuation of application No. 09/507,417, filed on Feb. 18, 2000, now abandoned.
Application No. 09/507,417 is a continuation-in-part of application No. 09/397,889, filed on Sep. 17, 1999.

(51) Int. Cl. H01J 37/30

(52) U.S. Cl. 264/485; 425/174.8 R

(57) ABSTRACT

A zoned web material having zones of radiation crosslinked elastomeric material with improved elevated temperature properties and lotion resistance. The elastomeric web comprises at least one first zone or region being characterized by a relatively high level of crosslinking and at least one second zone or region being characterized by a relatively low level of crosslinking. The zones of high crosslinking correspond to the zones of improved elastomeric properties, and can be made in virtually any predetermined pattern. In a preferred embodiment, the zoned web material is suitable for use in elasticized or body-hugging portions of disposable absorbent articles such as the side panels, waist bands, or cuffs of disposable diapers, or of health care products such as dressings, bandages and wraps. The zoned web material of the present invention may also be used in other portions of the absorbent articles where a stretchable portion of material is desired, such as stretchable topsheets or backsheets. The relatively highly crosslinked zones of the elastomeric material of the present invention preferably exhibit improved elastomeric properties at body temperature and under load or stress for a specified period of time, with or without lotion applied. In a preferred embodiment, the elastomeric material comprises block copolymers, such as polystyrene-butadiene-polystyrene block copolymers having a styrene content in excess of about 10 weight percent; an optional thermoplastic resin, such as vinylarene or polyolefins; and an optional processing oil, particularly a low viscosity hydrocarbon oil such as mineral oil. Also disclosed is a method of producing an elastomeric material of the present invention comprising providing a polymeric web, providing an electron beam generator, providing a mask, placing the mask adjacent the polymeric web in a predetermined position, and emitting electrons in a beam from the electron beam generator toward the polymeric web to crosslink the polymeric web until the web reaches a predetermined level of crosslinking.

### CROSS REFERENCE TO RELATED APPLICATION

This application is a continuation of U.S. application Ser. No. 09/507,417, filed Feb. 18, 2000, which is a continuation-in-part of U.S. application Ser. No. 09/397,889, filed Sep. 17, 1999.

### FIELD OF THE INVENTION

The present invention relates to radiation crosslinked elastomeric materials. In particular, this invention relates to the radiation crosslinking of regions, or zones, of elastomeric materials.

### BACKGROUND OF THE INVENTION

It has long been known in the field of disposable absorbent articles that it is desirable to construct products such as disposable diapers, pull-on diapers, training pants, sanitary napkins, pantiliners, incontinent briefs, bandages, wound dressings, and the like, with elastic elements to improve the range of size, ease of motion, and sustained fit. It is also well known that it is preferable, especially in such products intended to be worn in hot and humid conditions, to provide adequate porosity to all areas of the article where undue occlusion of the skin may cause sensitized skin or heat rash. Due to the nature of many disposable articles intended to be worn or applied next to the skin of a user, there is a high potential for skin irritation due to trapping of moisture and other body exudates between the elasticized portion of the article and the skin of the wearer. Elasticized portions of such articles are particularly prone to causing skin irritations as they tend to be more conformable to the body, and therefore more likely to occlude areas of the skin, often for long periods of time.

Disposable diapers and other absorbent articles fitted with elasticized leg cuffs or elasticized waist bands for a more comfortable fit, as well as providing for better leakage control, are known in the art. Often, the elasticity is accomplished with a heat treatment of polymeric materials that results in a desirable shirring or gathering of a portion of the diaper. One such method of treatment is disclosed in U.S. Pat. No. 4,681,580, issued to Reising et al. on Jul. 21, 1987, and hereby incorporated by reference herein. Other methods for imparting elasticity are taught in U.S. Pat. No. 5,143,679 issued to Weber et al. on Sep. 1, 1992, U.S. Pat. No. 5,156,793 issued to Buell et al. on Oct. 20, 1992 and U.S. Pat. No. 5,167,897 issued to Weber et al. on Dec. 1, 1992, all are hereby incorporated by reference herein.

Various other methods are known in the art for imparting elasticity to polymer films (as well as fibers, nonwoven webs, and the like) for use as the elastic portion of an absorbent article. Often, as materials with greater elasticity provide absorbent products with a better fit to the body, the air flow to the skin and the vapor flow from the occluded areas are reduced. Breathability (particularly vapor permeability) of the elastic material, for example by imparting porosity to a film, then becomes more important for skin health. Prior art web structures that do provide adequate porosity so as to be preferable for use as the wearer-contacting surface on disposable absorbent articles have been of two basic varieties, i.e., inherently fluid-pervious structures, such as fibrous nonwovens, and fluid-impervious materials such as polymeric webs which have been provided with a degree of fluid permeability via aperturing to permit fluid and moisture flow therethrough.

One material which has been successfully utilized as a body contacting surface in a disposable absorbent article context is disclosed in commonly assigned U.S. Pat. No. 4,342,314 issued to Radel et al. on Aug. 3, 1982, and hereby incorporated herein by reference. The Radel et al. patent discloses an improved macroscopically-expanded three-dimensional plastic web comprising a regulated continuum of capillary networks originating in and extending from one surface of the web and terminating in the form of apertures in the opposite surface thereof. In a preferred embodiment, the capillary networks are of decreasing size in the direction of liquid transport.

The macroscopically-expanded three-dimensional plastic web of the type generally described in the aforementioned Radel et al. patent has met with good success in permitting adequate vapor permeability due to the porosity provided by vacuum-formed apertures. However, because of material limitations such webs do not generally possess the requisite elasticity to allow the resulting web to have significant elastomeric characteristics. This shortcoming substantially limits the use of such webs in elasticized portions of an absorbent article.

An improvement in the aforementioned Radel et al. web for use in disposable absorbent articles is disclosed in commonly assigned, copending U.S. patent application Ser. No. 08/816,106 entitled Tear Resistant Porous Extensible Web, filed Mar. 14, 1997 in the name of Curro et al. (hereinafter Curro '106) and hereby incorporated herein by reference. The aforementioned Curro et al. application discloses elasticized polymeric webs made in accordance with the aforementioned Radel et al. patent, but which may be produced from elastomeric materials, or laminates of polymeric materials. Laminates of this type can be prepared by coextrusion of elastomeric materials, including block copolymers, and less elastic skin layers and may be used in the body hugging portions of absorbent garments, such as the waistband portions and leg cuffs.

One drawback to elastomeric compositions comprised of block copolymers is that the web can degrade when combined with a lotion, for example a skin care lotion applied to the surface of the web to protect or enhance skin care. Lotions used to enhance skin care can include petroleum-based components and/or other components that can be at least partly compatible with thermoplastics and block copolymers. If the lotions come into sufficient contact with the elastomeric portion of an elastomeric web, the elastic performance of the web can be significantly degraded in a relatively short period of time. The degradation of the elastic performance limits the web's usefulness in applications such as components of disposable absorbent diapers.

A further improvement in the elasticized web of the aforementioned Curro et al. which improves the lotion resistance of the web is the radiation cross-linked web disclosed in commonly assigned, copending U.S. patent application Ser. No. 09/397,889 entitled Radiation Crosslinked Elastomeric Materials, filed Sep. 17, 1999 in the name of Zhang et al. (hereinafter Zhang '889) and hereby incorporated herein by reference. Zhang '889 discloses methods of forming an elasticized web having lotion resistance as well as excellent body temperature performance by radiation crosslinking the web, preferably in a continuous process.

Despite the aforementioned improvements to elastomeric materials for use in disposable absorbent articles, the use conditions of the articles continually demand further technological improvements to increase article performance and user comfort. Further, the economic constraints of production continually demand further improvements in processing. For example, often the side panel, or “ear” fastening portion of a disposable diaper must be highly elastic, and added as a separate component to other (less elastic) components of the diaper during diaper production. However, if the entire side panel is crosslinked according to the teachings of Zhang '889, the portion used for attaching to the chassis of the diaper may not be thermally bondable, and may have to be attached by a less commercially-desirable method.

Accordingly, it would be desirable to provide a method for making an elastomeric web having “zones” or pre-selected portions of relatively higher elasticity.

It would also be desirable to provide a side panel of a diaper that can have highly elastic regions of crosslinked material, and other regions of uncrosslinked material that can be bonded by known methods.

It would also be desirable to provide an elastomeric web having “zones” or portions of relatively higher elasticity which can retain their elastic properties under actual use conditions of the finished product over a specified period of time, for example, at body temperature under sustained load for up to about 10 hours.

It would also be desirable to provide such an elastomeric web having “zones” or portions of relatively higher elasticity, the web being form-fitting and breathable or vapor permeable.

It is further desirable to provide an apertured elastomeric web having “zones” or portions of relatively higher elasticity, the web being designed to dissociate the effects of an applied strain on it from the edges of the apertures and hence retard or prevent the onset of tear initiation.

Furthermore, it is desirable to provide such an elastomeric web having “zones” or portions of relatively higher elasticity that is cost-effective for disposable absorbent articles, such as pull-on diapers, training pants, disposable diapers with fasteners, incontinence garments, sanitary napkins, pantiliners, wound dressings, bandages, and wraps.

### SUMMARY OF THE INVENTION

The present invention is a zoned web material having zones of radiation crosslinked elastomeric material with improved elevated temperature properties and lotion resistance. The elastomeric web comprises at least one first zone or region being characterized by a relatively high level of crosslinking and at least one second zone or region being characterized by a relatively low level of crosslinking. The zones of high crosslinking correspond to the zones of improved elastomeric properties, and can be made in virtually any predetermined pattern. In a preferred embodiment, the zoned web material is suitable for use in elasticized or body-hugging portions of disposable absorbent articles such as the side panels, waist bands, or cuffs of disposable diapers, or of health care products such as dressings, bandages and wraps. The zoned web material of the present invention may also be used in other portions of the absorbent articles where a stretchable portion of material is desired, such as stretchable topsheets or backsheets. The relatively highly crosslinked zones of the elastomeric material of the present invention preferably exhibit improved elastomeric properties at body temperature and under load or stress for a specified period of time, with or without lotion applied. In a preferred embodiment, the elastomeric material comprises block copolymers, such as polystyrene-butadiene-polystyrene block copolymers having a styrene content in excess of about 10 weight percent; an optional thermoplastic resin, such as vinylarene or polyolefins; and an optional processing oil, particularly a low viscosity hydrocarbon oil such as mineral oil.

Also disclosed is a method of producing an elastomeric material of the present invention comprising providing a polymeric web, providing an electron beam generator, providing a mask, placing the mask adjacent the polymeric web in a predetermined position, and emitting electrons in a beam from the electron beam generator toward the polymeric web to crosslink the polymeric web until the web reaches a predetermined level of crosslinking.

### BRIEF DESCRIPTION OF THE DRAWINGS

While the specification concludes with claims particularly pointing out and distinctly claiming the subject matter of the present invention, it is believed that the present invention will be better understood from the following description taken in conjunction with the accompanying drawings in which like reference numerals identify identical elements and wherein:

FIG. 1 is an enlarged, partially segmented, perspective illustration of a prior art polymeric web of a type generally disclosed in commonly assigned U.S. Pat. No. 4,342,314;

FIG. 2 is an enlarged, partially segmented, perspective illustration of a preferred elastomeric web of the present invention having two layers of polymer film, at least one of which is elastomeric;

FIG. 3 is a further enlarged, partial view of a web of the type generally shown in FIG. 2, but illustrating in greater detail the web construction of an alternative elastomeric web of the present invention;

FIG. 4 is an enlarged cross-sectional view of a preferred multilayer film of an elastomeric web of the present invention having an elastomeric layer interposed between two skin layers;

FIG. 5 is a plan view of aperture shapes projected in the plane of the first surface of an alternative elastomeric web of the present invention;

FIG. 6 is an enlarged cross-sectional view of an interconnecting member taken along section line 6-6 of FIG. 5;

FIG. 7 is another enlarged cross-sectional view of an interconnecting member taken along section line 7-7 of FIG. 5;

FIGS. 8A-8C are schematic representations of a cross-section of an aperture of an elastomeric web of the present invention in various states of tension;

FIG. 9 is a schematic representation of one embodiment of an apparatus for making the web of the present invention;

FIG. 10 is a schematic representation of one possible pattern for selectively radiation treating zones of an elastomeric web of the present invention;

FIG. 11 is a schematic representation of another embodiment of an apparatus for making the web of the present invention;

FIG. 12 is a schematic illustration of a beam exposure apparatus and electro-optic e-beam exposure system;

FIG. 13 is a partially segmented perspective illustration of a disposable article comprising the elastomeric web of the present invention;

FIG. 14 is a simplified, partially exploded perspective illustration of a laminate structure generally useful for forming the web structure illustrated in FIG. 2;

FIG. 15 is a perspective view of a tubular member formed by rolling a planar laminate structure of the type generally illustrated in FIG. 15 to the desired radius of curvature and joining the free ends thereof to one another;

FIG. 16 is a simplified schematic illustration of a preferred method and apparatus for debossing and perforating an elastomeric film generally in accordance with the present invention;

FIG. 17 is an enlarged, partially segmented perspective illustration of an alternative elastomeric web of the present invention; and

FIG. 18 is an enlarged cross sectional illustration of the web of FIG. 17 taken along section line 19-19.

### DETAILED DESCRIPTION OF THE PRESENT INVENTION

A preferred embodiment of a zoned radiation treated elastomeric material is now described with reference to the Drawing Figures. While the preferred embodiment described herein comprises a macroscopically-expanded, three-dimensional, fluid pervious polymeric web, the invention is not to be so limited. The improvement of the present invention may be practiced on non-apertured films, webs, nonwoven webs, and the like. However, for elastomeric materials having beneficial applications as components in disposable absorbent articles, the macroscopically-expanded, three-dimensional, fluid pervious polymeric web described below is the preferred web embodiment.

Fibers, strands and planar webs (or “sheets”) of material useful as webs of the present invention may be produced by methods known in the art for processing elastomeric materials. Three-dimensional, formed films, including coextruded formed films can be produced by the methods disclosed herein.

As used herein, the term “comprising” means that the various components, ingredient, or steps can be conjointly employed in practicing the present invention. Accordingly, the term “comprising” encompasses the more restrictive terms “consisting of” and ‘consisting essentially of””.

As used herein, the term “zone” refers to a portion or region of a web material that is differentiated from at least one other region in the same web material, preferably by the level of radiation-induced crosslinking of the material in that region.

As used herein, the terms “elastic” or “elastomeric” refer to any material which is capable of being elongated or deformed under an externally applied force, and which will substantially resume its original dimension or shape, sustaining only small permanent set (typically no more than about 20%), after the external force is released. The term “elastomer” refers to any material exhibiting elastic properties as described hereinabove.

As used herein, the term “thermoplastic” refers to any material which can be melted and resolidified with little or no change in physical properties (assuming a minimum of oxidative degradation).

As used herein, the term “percent elongation” refers to the difference between the length of an elastomeric material measured while the material is elongated under an applied force and the length of the material in its undeformed or unstrained state, dividing by the length of the material in its undeformed state, then multiplying by 100. For example, a material in its undeformed or unstrained state has a 0% elongation.

As used herein, the terms “set” or “percent set” refer to the percent deformation of an elastomeric material measured while the material is in a relaxed condition for a specified period of time (i.e., 60 seconds for the Test Methods described herein) after the material was released from a specified elongation without allowing the material to snap back completely. The percent set is expressed as [(zero load extension after one cycle—initial sample gauge length of cycle 1)/(initial sample gauge length of cycle 1)]×100. Zero load extension refers to the distance between the jaws at the beginning of the second cycle before a load is registered by the tensile testing equipment.

As used herein, the term “stress relaxation” refers to the percentage loss of tension or load between the maximum load or force encountered after elongating an elastomeric material at a specific rate of extension to a predetermined length (or the load or force measured at some initial length) and the remaining load or force measured after the sample has been held at that length or elongation for a specified period of time. Relaxation is expressed as percentage loss of the initial load encountered at a specific extension of an elastomeric material.

As used herein, the term “hysteresis” refers to the difference between the energy required to elongate the elastomeric material to the energy retained by the elastomeric material before retraction from a specified elongation. Stretching an elastomeric material sample to a specified elongation, typically 200% elongation, and returning to zero load completes a hysteresis loop.

Other terms are defined herein where initially discussed.

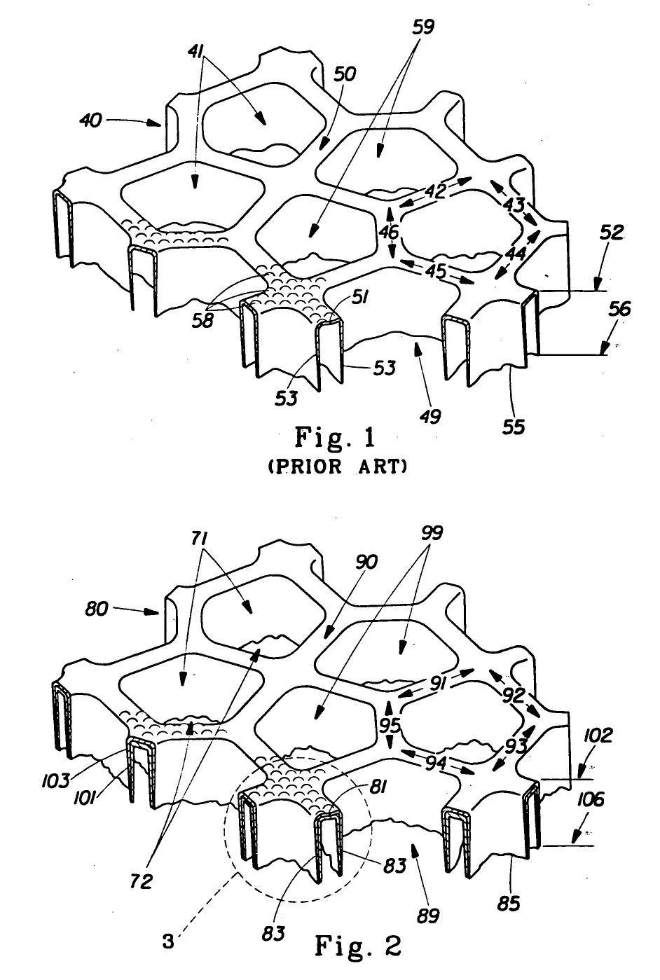

FIG. 1 is an enlarged, partially segmented, perspective illustration of a prior art macroscopically-expanded, three-dimensional, fiber-like, fluid pervious polymeric web 40 which has been found highly suitable for use as a topsheet in disposable absorbent articles, such as diapers and sanitary napkins. The prior art web is generally in accordance with the teachings of commonly assigned U.S. Pat. No. 4,342,314 issued to Radel et al. The fluid pervious web 40 exhibits a multiplicity of apertures, e.g., apertures 41, which are formed by a multiplicity of interconnected fiber-like elements, e.g., fiber-like elements 42, 43, 44, 45, and 46 interconnected to one another in the first surface 50 of the web. Each fiber-like element comprises a base portion, e.g., base portion 51, located in plane 52 of the first surface 50. Each base portion has a sidewall portion, e.g., sidewall portion 53, attached to each edge thereof. The sidewall portions extend generally in the direction of the second surface 55 of the web. The intersecting sidewall portions of the fiber-like elements are interconnected to one another intermediate the first and second surfaces of the web, and terminate substantially concurrently with one another in the plane 56 of the second surface 55.

In one embodiment, the base portion 51 includes a microscopic pattern of surface aberrations 58 generally in accordance with the teachings of U.S. Pat. No. 4,463,045, issued to Ahr et al. on Jul. 31, 1984, the disclosure of which is hereby incorporated herein by reference. The microscopic pattern of surface aberrations 58 provides a substantially non-glossy visible surface when the web is struck by incident light rays.

In an alternative embodiment the prior web may include a multiplicity of much smaller capillary networks (not shown) in the first surface 50 of the web, as taught by U.S. Pat. No. 4,637,819 to Ouellette et al. issued Jan. 20, 1987 and hereby incorporated herein by reference. It is believed that the additional porosity afforded by the smaller fluid-handling capillary networks may allow the web of the present invention function more efficiently when used as an extensible, porous portion of a disposable absorbent article.

As utilized herein, the term “interconnecting members” refers to some or all of the elements of the elastomeric web, portions of which serve to define the primary apertures by a continuous network. Representative interconnecting members include, but are not limited to, the fiber-like elements of the aforementioned '314 Radel et al. patent and commonly assigned U.S. Pat. No. 5,514,105 to Goodman, Jr., et al. issued on May 7, 1996 and hereby incorporated herein by reference. As can be appreciated from the following description and drawings, the interconnecting elements are inherently continuous, with contiguous interconnecting elements blending into one another in mutually-adjoining transition portions.

Individual interconnecting members can best be generally described, with reference to FIG. 1, as those portions of the elastomeric web disposed between any two adjacent primary apertures, originating in the first surface 50 and extending to the second surface 55. On the first surface of the web the interconnecting members collectively form a continuous network, or pattern, the continuous network of interconnecting members defining the primary apertures, and on the second surface of the web the interconnecting sidewalls of the interconnecting members collectively form a discontinuous pattern of secondary apertures.

As utilized herein, the term “continuous”, when used to describe the first surface of the elastomeric web, refers to the uninterrupted character of the first surface, generally in the plane of the first surface. Thus, any point on the first surface can be reached from any and every other point on the first surface without substantially leaving the first surface in the plane of the first surface. Likewise, as utilized herein, the term “discontinuous,” when used to describe the second surface of the elastomeric web, refers to the interrupted character of the second surface, generally in the plane of the second surface. Thus, any point on the second surface cannot be reached from every other point on the second surface without substantially leaving the second surface in the plane of the second surface.

In general, as utilized herein the term “macroscopic” is used to refer to structural features or elements which are readily visible to a normal human eye when the perpendicular distance between the viewer's eye and the plane of the web is about 12 inches. Conversely, the term “microscopic” is utilized to refer to structural features or elements which are not readily visible to a normal human eye when the perpendicular distance between the viewer's eye and the plane of the web is about 12 inches.

As utilized herein, the term “macroscopically-expanded”, when used to describe three-dimensional elastomeric webs, ribbons and films, refers to elastomeric webs, ribbons and films which have been caused to conform to the surface of a three-dimensional forming structure so that both surfaces thereof exhibit the three-dimensional pattern of the forming structure. Such macroscopically-expanded webs, ribbons and films are typically caused to conform to the surface of the forming structures by embossing (i.e., when the forming structure exhibits a pattern comprised primarily of male projections), by debossing (i.e., when the forming structure exhibits a pattern comprised primarily of female capillary networks), or by extrusion of a resinous melt onto the surface of a forming structure of either type.

By way of contrast, the term “planar” when utilized herein to describe plastic webs, ribbons and films, refers to the overall general condition of the web, ribbon or film when viewed by the naked eye on a macroscopic scale. For example, a non-apertured extruded film or an apertured extruded film that does not exhibit significant macroscopic deformation out of the plane of the film would generally be described as planar. Thus, for an apertured, planar web the edge of the material at the apertures is substantially in the plane of the web, causing applied web stresses in the plane of the web to be coupled directly to tear initiation sites at the apertures.

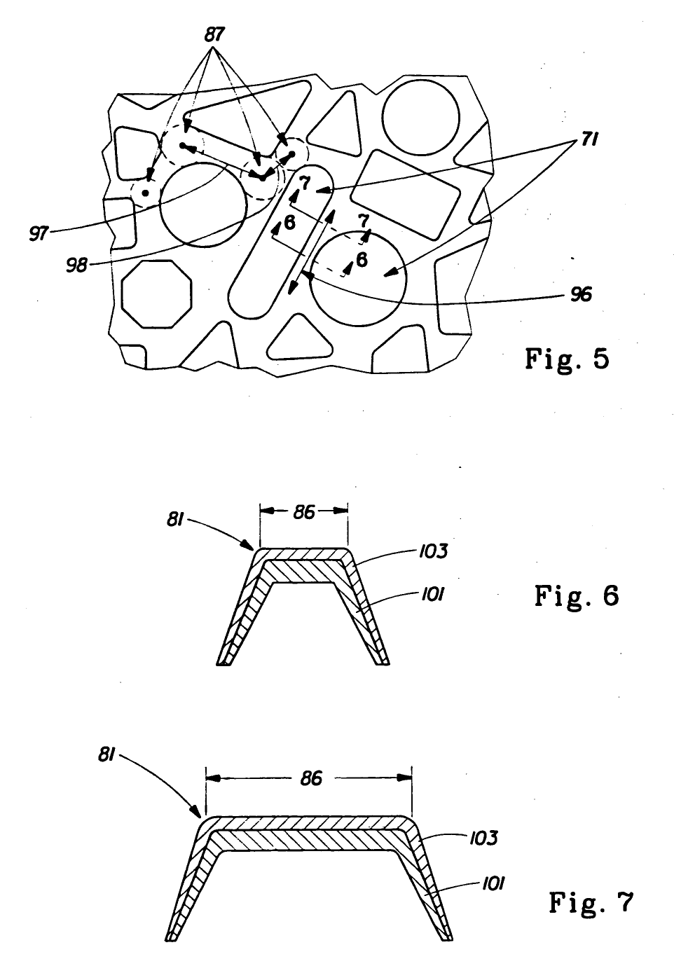

When macroscopically-expanded, the multilayer film of the elastomeric web of the present invention is formed into three-dimensional interconnecting members which may be described as channel-like. Their two-dimensional cross-section may also be described as “U-shaped”, as in the aforementioned Radel et al. patent, or more generally as “upwardly concave-shaped”, as disclosed in the aforementioned Goodman, Jr., et al. patent. “Upwardly concave-shaped” as used herein describes the orientation of the channel-like shape with relation to the surfaces of the elastomeric web, with the base generally in the first surface, and the legs of the channel extending from the base in the direction of the second surface, and with the channel opening being substantially in the second surface. In general, as described below with reference to FIGS. 5, 6 and 7, for a plane extending through the web orthogonal to the plane of the first surface and intersecting any two adjacent primary apertures, the resulting cross-section of an interconnecting member disposed between will exhibit a generally upwardly concave shape that may be substantially U-shaped.

It has been discovered that if a planar elastomeric web can be formed into a macroscopically-expanded, three-dimensional, fluid pervious web, generally in accordance with the teachings of the aforementioned '314 Radel et al. patent, the resulting three-dimensional elastomeric web exhibits the advantages of high porosity and high elasticity, as well as reliability, and high strength. Such an improvement is disclosed in the aforementioned Curro '106 patent application. The Curro '106 invention utilizes a multilayer polymeric web comprising an elastomeric layer in combination with at least one skin layer, and forming the multilayer web into a macroscopically-expanded, three-dimensional configuration.

An improvement to Curro '106 is disclosed in the aforementioned Zhang '889 patent application. The Zhang '889 invention utilizes radiation crosslinking to impart superior elastomeric properties to a web. In particular, the web of Zhang '889 exhibits superior elastomeric performance over un-radiated webs when tested at elevated temperatures, such as body temperature.

The present invention is an improvement over Zhang '889, and in particular improves the web of Zhang by imparting relatively higher elasticity selectively in certain regions or portions of the web being elasticized. Therefore, rather than treat an entire web to impart elasticity, as disclosed in Zhang '889, the improvement of the present invention involves selectively imparting or modifying elasticity to certain parts or regions of the web, and not others. Such “zoned” or selective treatment of portions of the web permits a cost savings in production, faster production, and a very versatile material design window. By the improvement of the present invention, selected portions of the web can be elasticized to the necessary degree, without the need to elasticize the entire web to the same degree. Such design flexibility permits an almost infinite range of elastic performance parameters for a web for use in a disposable absorbent article. For example, a backsheet, as disclosed below, may be selectively elasticized in the waist region or leg cuff region only. Moreover, certain regions of a web can be left un-crosslinked, thereby facilitating thermal bonding techniques in that region.

Preferably, the elastomeric layer itself is capable of undergoing from 50% to 1500% elongation at room temperature when in a non-apertured, planar condition. In general, the maximum elongation occurs before crosslinking, with the elongation decreasing proportionally with the level of electron beam radiation. The elastomer can be either a pure elastomer, or a blend with an elastomeric phase or content that will still exhibit substantial elastomeric properties at ambient temperatures, and elevated temperatures, such as human body temperatures.

The skin layer of the web of the present invention, if used, is preferably thinner and substantially less elastic than the elastomeric layer, and may in the limiting case be generally inelastic. There may be more than one skin layer used in conjunction with the elastomeric layer of the present invention, and it, or they, will generally modify the elastic properties of the elastomer. If more than one skin layer is used, the skin layers may have the same or different material characteristics.

FIG. 2 is an enlarged partially segmented, perspective illustration of a macroscopically-expanded, three-dimensional, elastomeric web embodiment of the present invention, generally indicated as 80. The geometrical configuration of the fluid-pervious, elastomeric web 80 is generally similar to that of prior art web 40, illustrated in FIG. 1, and is generally in accordance with the teachings of the aforementioned '314 Radel et al. patent. Other suitable formed film configurations are described in U.S. Pat. No. 3,929,135, issued to Thompson on Dec. 30, 1975; U.S. Pat. No. 4,324,246 issued to Mullane, et al. on Apr. 13, 1982; and U.S. Pat. No. 5,006,394 issued to Baird on Apr. 9, 1991. The disclosures of each of these patents are hereby incorporated herein by reference.

A preferred embodiment of an elastomeric web 80 of the present invention exhibits a multiplicity of primary apertures, e.g., primary apertures 71, which are formed in plane 102 of the first surface 90 by a continuous network of interconnecting members, e.g., members 91, 92, 93, 94, 95 interconnected to one another. The shape of primary apertures 71 as projected on the plane of the first surface 90 are preferably in the shape of polygons, e.g., squares, hexagons, etc., in an ordered or random pattern. In a preferred embodiment each interconnecting member comprises a base portion, e.g., base portion 81, located in plane 102, and each base portion has a sidewall portion, e.g., sidewall portions 83, attached to each edge thereof. The sidewall portions 83 extend generally in the direction of the second surface 85 of the web and intersect with side walls of adjoining interconnecting members. The intersecting sidewall portions are interconnected to one another intermediate the first and second surfaces of the web, and terminate substantially concurrently with one another to form a secondary aperture, e.g., secondary apertures 72 in the plane 106 of the second surface 85. Detailed description of the porous macroscopically-expanded, three-dimensional elastomeric web is disclosed in aforementioned Curro '106 patent application.

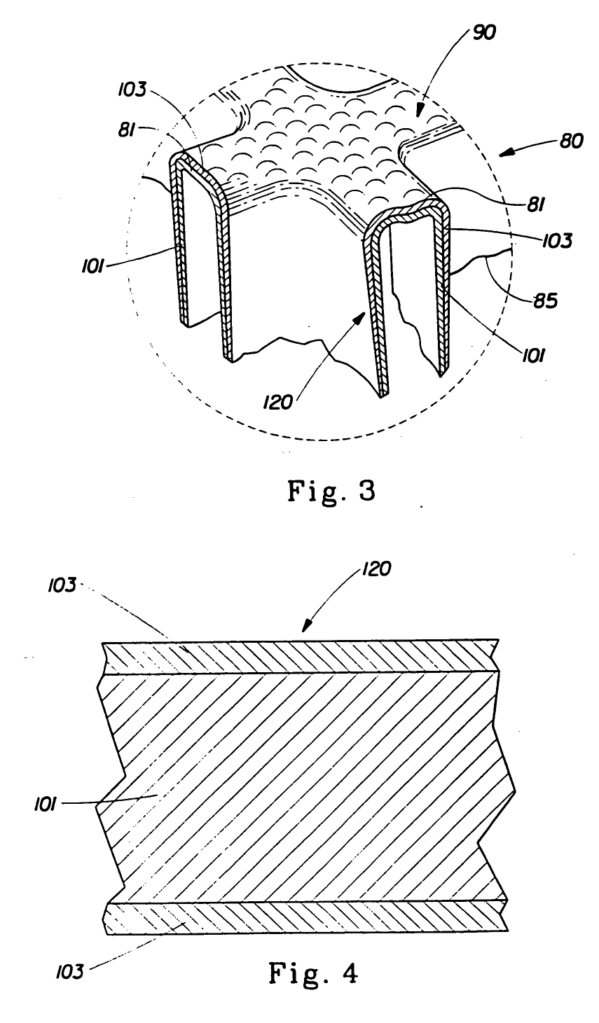

FIG. 3 is a further enlarged, partial view of a web of the type generally similar to web 80 of FIG. 2, but illustrating an alternative web construction according to the present invention. The multilayer polymeric formed film 120 of web 80 is preferably comprised of at least one elastomeric layer 101, and at least one skin layer 103. While FIG. 3 shows a two-layer embodiment with the skin layer 103 nearer the first surface 90, it is believed that the order of layering of the formed film 120 is not limiting. While it is presently preferred that as shown in FIG. 3 the polymeric layers terminate substantially concurrently in the plane of the second surface, it is not presently believed to be essential that they do so, i.e., one or more layers may extend further toward the second surface than the others. The elastomeric layer comprises from about 20% to about 95% of the total thickness of the film and each skin layer comprises from about 1% to about 40% of the total thickness of the film. Typically, the elastomeric film has a thickness of from about 0.5 mils to about 20 mils, preferably from about 1.0 mil to 5.0 mils. Each skin layer is typically about 0.05 mil to about 5 mils thick, and preferably from about 0.1 mil to about 1.5 mils thick. In one embodiment, the elastomeric layer is about 3.2 mils thick and each skin layer is about 0.15 mil thick.

A particularly preferred multilayer polymeric film 120 of the web 80 is depicted in cross-section in FIG. 4, showing an elastomeric layer 101 interposed between two skin layers 103. The elastomeric layer 101 preferably comprises a thermoplastic elastomer having at least one elastomeric portion and at least one thermoplastic portion. The thermoplastic elastomer typically comprises a substantially continuous amorphous matrix, with glassy or crystalline domains interspersed throughout. Not intending to be bound by theory, it is believed that the discontinuous domains act as effective physical crosslinks and hence enabling the material to exhibit an elastic memory when the material is subjected to an applied strain and subsequently released. Preferred thermoplastic elastomeric materials include block copolymers and blends thereof. The thermoplastic elastomeric materials suitable for use in the present invention include styrene-butadiene-styrene or other such common styrenic block copolymers. The skin layers preferably comprise substantially less elastomeric materials such as polyolefins having densities greater than about 0.90 g/cc, which are capable of thermoplastic processing into thin films. The skin layer should have sufficient adhesion to the elastomeric layer such that it will not completely delaminate either before or after stretching of the web. The materials suitable for use herein as the skin layer should have the desired melt flow properties such that it can be successfully processed with the elastomeric layer to form a multilayer film. A preferred method to produce the multilayer polymeric film 120 is coextrusion.

In general, an elastomeric material of the present invention with desired elastic and stress relaxation properties may be prepared from a composition which comprises at least one elastomeric block copolymer, an optional thermoplastic polymer and an optional low viscosity processing oil. A typical composition can comprise about 55 wt % of a styrenic-olefinic triblock copolymer, about 15 wt % of thermoplastic additive such as polystyrene, and about 30 wt % of mineral oil. The composition may further include other additives such as crosslinking promoters, antioxidants, anti-block agents and anti-slip agents. Typically the antioxidants are no more than 1%, preferably no more than 0.5% of the total weight of the elastomeric compositions.

A number of block copolymers can be used to prepare the elastomeric compositions useful in preparing the low stress relaxation elastomeric film, fiber, strand or sheet of the present invention. Linear block copolymers, such as A-B-A triblock copolymers, A-B-A-B tetrablock copolymers, A-B-A-B-A pentablock copolymers, or the like, are suitably selected on the basis of endblock content and endblock average molecular weight. Such block copolymers generally comprise an elastomeric block portion B and a thermoplastic block portion A. The block copolymers suitable for use herein generally have a three-dimensional physical crosslinked or entangled structure below the glass transition temperature (T_{g}) of the thermoplastic block portion. The block copolymers suitable for use herein are thermoplastic and elastomeric. The block copolymers are thermoplastic in the sense that they can be melted above the endblock T_{g}, formed, and resolidified several times with little or no change in physical properties (assuming a minimum of oxidative degradation).

In such copolymers, the block portion A are the hard blocks and are derived from materials which have a sufficiently high glass transition temperature to form crystalline or glassy domains at the use temperature of the polymer. Such hard blocks generally form strong physical entanglements or agglomerates with other hard blocks in the copolymers. The hard block portion A generally comprises a polyvinylarene derived from monomers such as styrene, α-methyl styrene, other styrene derivatives, or mixtures thereof. The hard block portion A preferably is polystyrene, having a number-average molecular weight between from about 1,000 to about 200,000, preferably from about 2,000 to about 100,000, more preferably from about 5,000 to about 60,000. Typically the hard block portion A comprises from about 10% to about 80%, preferably from about 20% to about 50%, more preferably from about 25 to about 35% of the total weight of the copolymer.

The material forming the B-block will have sufficiently low glass transition temperature at the use temperature of the polymer such that crystalline or glassy domains are not formed at these working temperatures. The B-block may thus be regarded as a soft block. The soft block portion B is typically an olefinic polymer derived from conjugated aliphatic diene monomers of from about 4 to about 6 carbon atoms or linear alkene monomers of from about 2 to about 8 carbon atoms. Without being bound by theory, it is believed that linear alkene monomers useful for the present invention can be made with as high as 8, 10, 12, 14, or higher numbers of carbon atoms. Suitable diene monomers include butadiene, isoprene, and the like. Suitable alkene monomers include ethylene, propylene, butylene, and the like. The soft block portion B preferably comprises a substantially amorphous polyolefin such as ethylene/propylene polymers, ethylene/butylene polymers, polyisoprene, polybutadiene, and the like or mixtures thereof, having a number-average molecular weight from about 1,000 to about 300,000, preferably from about 10,000 to about 200,000, and more preferably from about 20,000 to about 100,000. Typically the soft block portion B comprises from about 20% to about 90%, preferably from about 50% to about 80%, more preferably from about 65% to about 75% of the total weight of the copolymer.

Particularly suitable block copolymers for use in this invention comprise at least one substantially elastomeric midblock portion B and at least two substantially thermoplastic endblock portions A. Also suitable for use herein are triblock copolymers having thermoplastic endblocks A and A′, wherein A and A′ may be derived from different vinylarene monomers. The olefin block typically comprises at least about 50 percent by weight of the block copolymer. The unsaturation in olefinic double bonds may be selectively hydrogenated. For example, a polyisoprene block can be selectively reduced to form an ethylene-propylene block. The vinylarene block typically comprises at least about 10 percent by weight of the block copolymer. However, higher vinylarene content is more preferred for high elastic and low stress relaxation properties. The block copolymers may also be radial, having three or more arms, each arm being an B-A, B-A-B-A, or the like type copolymer and the B blocks being at or near the center portion of the radial polymer. Good results may be obtained with, for example, four, five, or six arms.

The block copolymer may be used in the elastomeric composition of the present invention in an amount effective to achieve the desired initial elastic and stress relaxation properties. The block copolymer will generally be present in the elastomeric composition in an amount typically from about 20 to about 80 weight percent, preferably from about 30 to about 70 weight percent, and more preferably from about 40 to about 60 weight percent of the elastomeric composition.

Suitable for use in the present invention are styrene-olefin-styrene triblock copolymers such as styrene-butadiene-styrene (S-B-S), styrene-ethylene/butylene-styrene (S-EB-S), styrene-ethylene/propylene-styrene (S-EP-S), styrene-isoprene-styrene (S-I-S), and mixtures thereof. The block copolymers may be employed alone, in a blend of block copolymers, or in a blend of one or more block copolymers with one or more thermoplastic polymers such as polystyrene, poly(α-methyl styrene), polypropylene, polyethylene, polybutylene, polyisoprene, copolymers of ethylene with various monomers as known in the art, or mixtures thereof. The block copolymers employed preferably only have minor quantities of, and most preferably essentially no, such other polymers present.

Particularly preferred block copolymers for use herein are polystyrene-butadiene-polystyrene block copolymers having a styrene content in excess of about 10 weight percent. With higher styrene content, the polystyrene endblock portions generally have a relatively high molecular weight. Such linear block copolymers of styrene-butadiene-styrene (S-B-S) are commercially available under the trade designation KRATON® D series from the Shell Chemical Company, Huston, Tex., and copolymers marketed under the trade name VECTOR®0 by Dexco Polymers, Houston, Tex. All the styrenic-olefinic block copolymers described herein are suitable for use in the elastomeric materials of the present invention either alone or in mixtures thereof.

Various thermoplastic polymers may be used in the elastomeric material of the present invention. Suitable thermoplastic polymers can associate with either the hard blocks or the soft blocks of the block copolymers to form an entangled three-dimensional network. Thermoplastic polymers such as polyphenylene oxide, and polyvinylarenes including polystyrene, poly(α-methyl styrene), polyvinyl toluene, and the like, are useful in the present invention. These polymers are chemically compatible with the styrenic hard blocks of the block copolymer. Thermoplastic polymers such as polyethylene, polypropylene, copolymers of olefins such as copolymers of ethylene with propylene, 1-butene, 1-hexane, 1-octene, vinylacetate, methacrylate, acrylic acid, and the like are also useful in the present invention. These polymers are chemically compatible with the olefinic soft blocks of the block copolymers. It is believed to be advantageous for the components to be compatible with either the hard blocks or the soft blocks of the block copolymer such that they may more easily form an entangled three-dimensional network structure, and they do not physically separate to a significant extent from the network structure.

The thermoplastic polymers or resin blends are generally in an amount typically from about 3 to about 60 weight percent, preferably from about 5 to about 40 weight percent, and more preferably from about 10 to about 30 weight percent of the low stress relaxation elastomeric composition used in the present invention.

Even though both end block associating polymers such as polystyrene, low molecular weight aromatic hydrocarbon resins and soft block associating polymers such as polypropylene or polyethylene may provide lower melt viscosity and promote processability of the composition, it has been found that additional processing aid such as a hydrocarbon oil, is beneficial for further lowering the viscosity and enhancing processability. The oil decreases the viscosity of the elastomeric composition such that the elastomeric composition becomes more processable. However, the processing oil tends to decrease the elastomeric tensile properties of the compositions. Preferably the processing oil is present in an amount up to about 60 wt %, preferably from about 5 to about 60 wt %, more preferably from about 10 to about 50 wt %, and most preferably from about 15 to about 45 wt % of the elastomeric compositions.

In a preferred embodiment, the processing oil is compatible with the composition, and is substantially non-degrading at the processing temperature. Suitable for use herein are hydrocarbon oils which may be linear, branched, cyclic, aliphatic or aromatic. Preferably the processing oil is a white mineral oil available under the tradename BRITOL® from Witco Company, Greenwich, Conn. Also preferred as the processing oil is another mineral oil under the tradename DRAKEOL® from Pennzoil Company Penrenco Division, Kams City, Pa.

In general, an elastomeric composition with desirable elastic properties may be prepared from a composition that comprises essentially only a block copolymer. However, such a composition will generally be very difficult to process because of high viscosity and high stretchy and tacky nature of the composition. In addition, the inherent tackiness of the elastomeric composition makes it difficult to handle. For example, the composition may be processed into a film which tends to stick to the processing equipment and is difficult to remove from the equipment, or when the composition have been processed and wound up, it tends to fuse together and becomes very difficult to unwound for further processing into the finished product.

It has been found that blending the neat block copolymer with other thermoplastic polymers as well as processing oils improves the processability and handling of the composition. The thermoplastic polymers and processing oil tend to reduce the viscosity of the composition and provide improved processability of the composition. To further improve the processability and handling of the composition, especially when a film of such elastomeric composition is desired, at least one skin layer of a substantially less elastomeric material may be coextruded with the elastomeric composition. In a preferred embodiment, the elastomeric composition is coextruded with thermoplastic compositions to provide an elastomeric center layer between two skin layers, each being substantially joined to one side of the center layer. The two skin layers may be the same or different thermoplastic materials.

The skin layer is preferably at least partially compatible or miscible with a component of the elastomeric block copolymers such that there is sufficient adhesion between the center elastomeric layer and the skin layer for further processing and handling. The skin layer may comprise thermoplastic polymers or blends of thermoplastic polymers and elastomeric polymers such that the skin layer is substantially less elastomeric than the center elastomeric layer. Typically, the permanent set of the skin layer is at least about 20%, preferably at least about 30%, more preferably at least about 40% greater than that of the elastomeric center layer. Thermoplastic polymers suitable for use as the skin layer may be a polyolefin derived from monomers such as ethylenes, propylenes, butylenes, isoprenes, butadienes, 1,3-pentadienes, α-alkenes including 1-butenes, 1-hexenes, and 1-octenes, and mixtures of these monomers, an ethylene copolymers such as ethylene-vinylacetate copolymers (EVA), ethylene-methacrylate copolymers (EMA), and ethylene-acrylic acid copolymers, a polystyrene, a poly(α-methyl styrene), a polyphenylene oxide, and blends thereof. Additionally, tie layers may be used to promote adhesion between the center elastomeric layer and the thermoplastic skin layer.

FIG. 5 is a plan view of alternative primary aperture shapes projected in the plane of the first surface of an alternative elastomeric web of the present invention. While a repeating pattern of uniform shapes is preferred, the shape of primary apertures, e.g., apertures 71, may be generally circular, polygonal, or mixed, and may be arrayed in an ordered pattern or in a random pattern. Although not shown, it is understood that the projected shape may also be elliptical, tear-drop shaped, or any other shape, that is, the present invention is believed to be aperture-shape independent.

The interconnecting elements are inherently continuous, with contiguous interconnecting elements blending into one another in mutually-adjoining transition zones or portions, e.g., transition portions 87, shown in FIG. 5. In general, transition portions are defined by the largest circle that can be inscribed tangent to any three adjacent apertures. It is understood that for certain patterns of apertures the inscribed circle of the transition portions may be tangent to more than three adjacent apertures. For illustrative purposes, interconnecting members may be thought of as beginning or ending substantially at the centers of the transition portions, such as interconnecting members 97 and 98. Likewise, the sidewalls of the interconnecting members can be described as interconnecting to sidewalls of contiguous interconnecting members at areas corresponding to points of tangency where the inscribed circle of the transition portion is tangent to an adjoining aperture.

Exclusive of the transition zones, cross-sections transverse to a center line between the beginning and end of interconnecting members are preferably of generally uniform U-shape. However, the transverse cross-section need not be uniform along the entire length of the interconnecting member, and for certain aperture configurations it will not be uniform along most of its length. For example, as can be understood from the sectional illustrations of FIGS. 5 and 6, for interconnecting member 96, the width dimension, 86, of the base portion 81 may vary substantially along the length of the interconnecting member. In particular, in transition zones or portions 87, interconnecting members blend into contiguous interconnecting members and transverse cross-sections in the transition zones or portions may exhibit substantially non-uniform U-shapes, or no discernible U-shape.

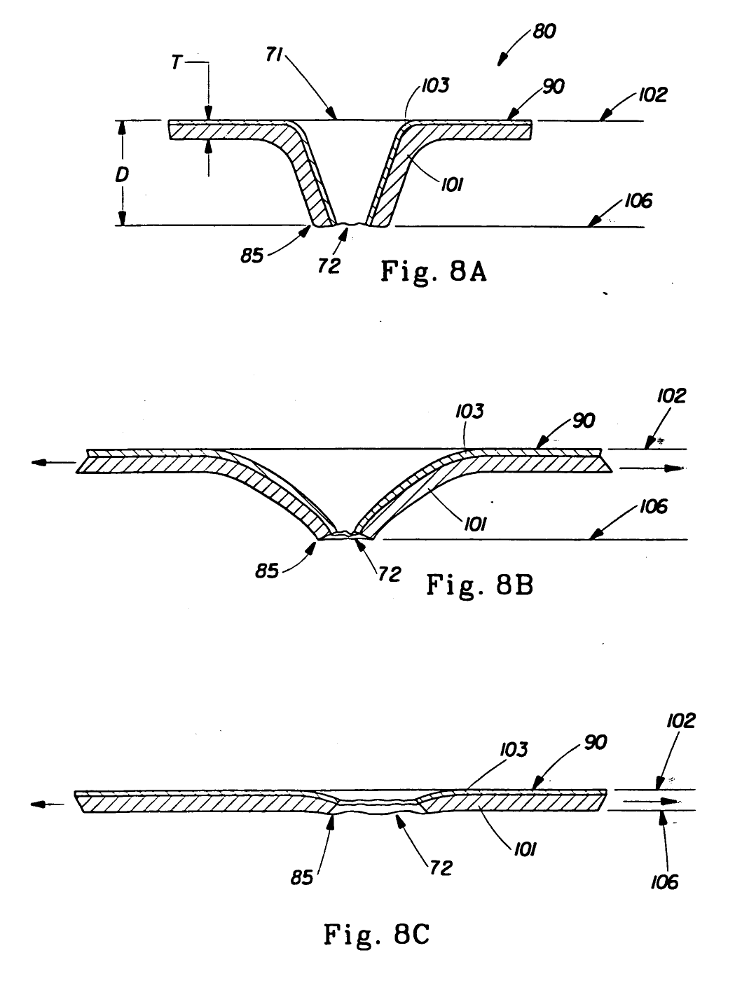

Without wishing to be bound by theory, it is believed that the web of the present invention is more reliable (i.e., resistant to catastrophic failure) when subjected to strain-induced stress due to the mechanism depicted schematically in cross section in FIGS. 8A-8C. FIG. 8A shows a primary aperture 71 in plane 102 of first surface 90, and a secondary aperture 72 in plane 106 of second surface 85, remote from plane 106 of first surface 90, of web 80 in an unstressed condition. When web 80 is stretched in the direction generally shown by arrows in FIG. 8B, first surface 90 is strained, and primary aperture 71 is likewise strained into a deformed configuration. However, the perimeter of primary aperture 71 is formed by the interconnecting members in a continuous first surface. Therefore, aperture 71 has no “edges” for tear initiation sites to compromise the elastic reliability of the web. The edges of the secondary aperture 72, being possible tear initiation sites, do not experience appreciable strain-induced stresses until the web is strained to the point where plane 102 is no longer remote from plane 106 of the first surface 90, as depicted in FIG. 8C. At the point where planes 102 and 106 are no longer remote, web 80 begins to behave essentially as a planar, apertured web.

It is instructive to consider the ratio of overall web depth, “D” in FIG. 8A, to film thickness, “T” in FIG. 8A of an unstretched elastomeric web. This ratio of D/T may be termed the draw ratio, as it pertains to the amount of film drawn out of the plane of the first surface due to the forming process of the present invention. Applicant believes that, in general, an increase in the draw ratio serves to increase resistance to tear by placing the second surface more remote from the first surface.

Without wishing to be bound by theory, it is believed that when the web 80 is strained or stretched, the elastomeric layer 101 of the present invention allows the base 81 of the interconnecting members forming a continuous web in the continuous first surface 90 to stretch. Skin layer 103 helps maintain the three-dimensional nature of the web, despite the applied stress, allowing the strain on the continuous first surface 90 and the resulting deformation of primary apertures 71 to be at least partially dissociated from the discontinuous second surface thereby minimizing strain at secondary apertures 72. Therefore the strain-induced stress at the continuous first surface of the web is substantially decoupled from potential strain-induced stress at tear initiation sites on the discontinuous second surface, at least until the secondary apertures begin to enter the plane of the first surface. This substantial dissociation, or decoupling, of the strain-induced stress of the web from strain-induced stress at the secondary apertures significantly increases web reliability by allowing repeated and sustained strains of the web up to about 100%, 200%, 300%, 400% or more without failure of the web due to tear initiation at the apertures.

One drawback to elastomeric compositions comprised of block copolymers is that the web can degrade when combined with a lotion, for example a skin care lotion applied to the surface of the web to protect or enhance skin care. Lotions used to enhance skin care can include petroleum-based components and/or other components that can be partly compatible with thermoplastics and block copolymers. If the lotions come into sufficient contact with the elastomeric layer of an elastomeric web, the elastic performance of the web can be significantly degraded. The degradation of the elastic performance limits the web's usefulness in applications such as components of disposable absorbent articles.

To prevent premature degradation of the elastomeric web of the present invention, it has been discovered that by cross-linking the elastomeric web the web exhibits a significant improvement in lotion degradation resistance. As further shown below, the beneficial increase in lotion resistance is accompanied by an increase in the body-temperature elastic performance of the material. Therefore, the material of the present invention provides for at least two benefits as an elastic component in disposable absorbent articles, both of which alone are a significant improvement over the prior art.

However, cross-linking the entire web may not be necessary or desirable in many applications. For example, when used in disposable absorbent articles, it may be necessary to elasticize and/or make lotion resistant only a small portion of the overall web. For example, it may be necessary to make a continuous web elasticized or lotion resistant in the portions, or zones, of a polymer film which will ultimately become the waist band, fastener, and/or leg cuff portion of a disposable diaper. Therefore, as disclosed herein, by selectively radiation treating only a portion of the overall web, the web performance can be significantly improved by tailoring the elastic properties in two dimensions, producing potentially complex patterns of elasticity. Patterns can be infinitely varied, and pattern changes can be made easily and relatively quickly via the use of an electronic programmable controller. Further, by selectively radiation treating production costs can be decreased due to faster production cycle times. That is, the entire film or web need not be irradiated to the same degree. Relatively small portions of a film or web can be irradiated to a certain level in a proportionally decreased period of time.

Selective crosslinking by radiation of the pre-determined zones of the block copolymer material is preferably accomplished by exposing the material to be crosslinked (e.g., film, tape, or fiber) to irradiation by radiation methods known in the art, while masking off certain portions of the material in which radiation treatment is not desired. The source of radiation is preferably an electron beam generator, but in principle a gamma radiation source may be used also. The radiation energy applied may vary, depending in part on the thickness of the material being radiated. Radiation is measured in rads, and can be expressed in megarads (Mrads). A suitable radiation dosage for flat films having a basis weight of about 70 grams per square meter (gsm) generally appears to be between 0 and 35 Mrad, and can be between about 1 and 25 Mrad, and is currently preferably about 3 and 15 Mrad.

The material may be exposed to radiation at reduced, elevated or atmospheric pressure under various purging gases, including air, nitrogen, argon, and may be carried out at room temperature or at a reduced or elevated temperature. It is believed that pressure and temperature need only be chosen so as not to disturb material physical properties. For example, the process of irradiating the material should be carried out below the melting point of the film itself. The irradiation can be done by passing the article under a radiation source or between two or more radiation sources. The irradiation can be done as a batch process, one item at a time, or it may be carried out continuously as in continuous web processing.

The radiation source is preferably an electron beam donor, but, as noted above, in principle a gamma radiation source may be used also. In a typical e-beam process electrons are generated when high voltage is applied to tungsten wire filaments inside a vacuum chamber. The filaments are heated electrically, glow white hot and generate a cloud of electrons. Electrons are then drawn from the cloud to areas of lesser voltage at extremely high speeds. After exiting the vacuum chamber through titanium foil they penetrate the web materials, effecting crosslinking.

Depending on design, the e-beam radiation can be either a batch process or a continuous process for fibers, nonwoven webs made from fibers, or film web process. For batch processing web materials, the web materials are placed inside a chamber, and electron beams are accelerated toward the web surface and penetrate the web. After a sufficient amount of radiation has penetrated the web, the radiation is stopped and the web material is removed. In general, it is believed that continuous processing methods are primarily beneficial for web materials, which includes both nonwoven webs and film webs. For continuous processing, a curtain of electron beams are generated at high speed as web materials are passed through at a uniform speed, with certain areas, or zones, masked from the e-beam curtain to avoid radiation treating those areas. Electron beam treatment may also be carried out in line with the material production, so that it is not necessary to produce the material separate from the crosslinking process.

The level of crosslinking induced in the material depends primarily on the radiation dosage and depth of penetration. Dosage can be defined as the amount of energy deposited on the material. The units of dosage are usually rads, or more commonly, megarads (Mrads). The dosage can be formulated as:
Dosage=K*I/S
where
   D=dosage (Mrads)
   K=e-beam system yield
   I=electron current (mA)
   S=web speed (m/min)

The depth of penetration is determined by the voltage. Higher voltages will generate higher speed of electrons for deeper penetration. For certain web thicknesses, electron voltage is normally fixed at predetermined values for optimal penetration and electron current is also fixed at predetermined values depending on the treatment level (dose) and desired web speed. A currently preferred continuous web e-beam apparatus and process can be obtained from Energy Sciences, Inc. of Wilmington, Mass.

Various patterns of zoned radiation treatment can be made by methods disclosed herein. For example, simple stripes or bands of radiation treated webs can be produced in a continuous process by passing the continuous web under a “curtain” of radiation, as described above, and masking a portion of the curtain, such that a “shadow” is cast on the web in the portions that are not to be treated. The mask or masks can be stationary, for generally parallel, straight bands, or moveable in a cross-direction dimension, such that a series of wavy, or sinusoidally varying bands can be produced.

The mask used in the processes described herein can be metalicized tapes, lead plates, electrically and preferably thermally conductive films, sheets, and other materials known in the art, including conductive polymers. Without being bound by theory, it is believed that an ideal mask serves to both safely conduct electrons away, and to safely convert excess energy into heat.

Another method for producing bands of selectively treated zones of elasticized material is to substitute multiple tungsten filaments in the e-beam emitter in place of the single filament now utilized. The individual filaments can be placed inside the same vacuum chamber, but separated by spacers such that the e-beam produced by each filament can be “focused” or directed by methods known in the art in the direction necessary to produce the desired pattern of radiation treatment.

As shown schematically in FIG. 9, in one embodiment of the method of the present invention comprises using a patterned mask having a series of repeating patterns on an endless belt system. An e-beam radiation source 200 is positioned so as to emit e-beam radiation 202 toward the web 210 to be radiated. As the web 210 is moved in the machine direction MD, at a predetermined speed, a continuous web or endless belt 220 is configured such that a portion moves near or adjacent the web 210 at the same predetermined speed in the same direction. Belt 220 is guided by a series of appropriately placed pulleys or rollers 204, and serves as a mask to prevent e-beam radiation from reaching web 210 in predetermined patterns. The patterns are formed by removing material from pre-selected areas of belt 220, such that e-beam radiation is permitted to reach web 210 in corresponding areas, or zones. That is, the belt 220 masks, or blocks, the e-beam radiation from reaching portions of web 210 except in pre-selected openings configured in a pattern that dictates the pattern of the radiated portions of web 210. E-beam radiation source 200 can be configured as an “arm” that extends into the operative position in a cantilevered manner. E-beam radiation 202 can be a continuous “curtain” of radiation, or be divided into discrete sections of radiation as described above as one alternative for producing bands of radiation treated zones.

Other methods of masking or selectively radiating a film or web are contemplated. For example, the film or web can be imprinted with a pattern of radiation absorbing material that prevents or hinders the radiated electrons from entering the film or web. Also, radiation blocking release tape can be applied to the film or web prior to e-beam radiating. These and similar methods and technologies are considered to be “masks” for the purposes of the present invention.

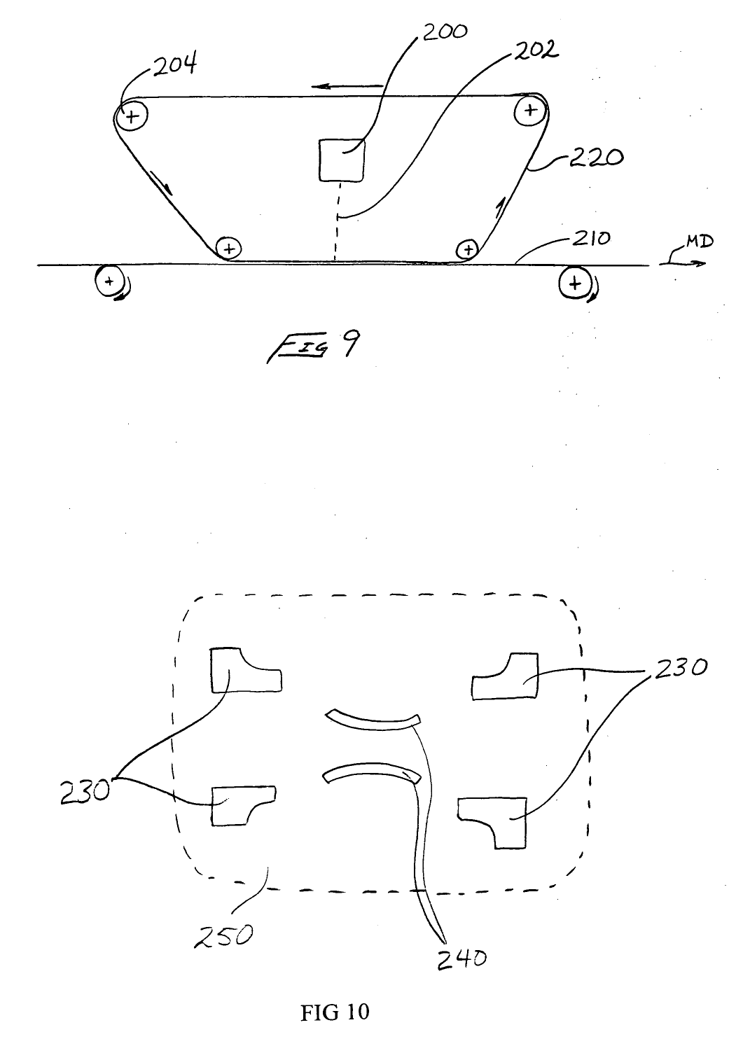

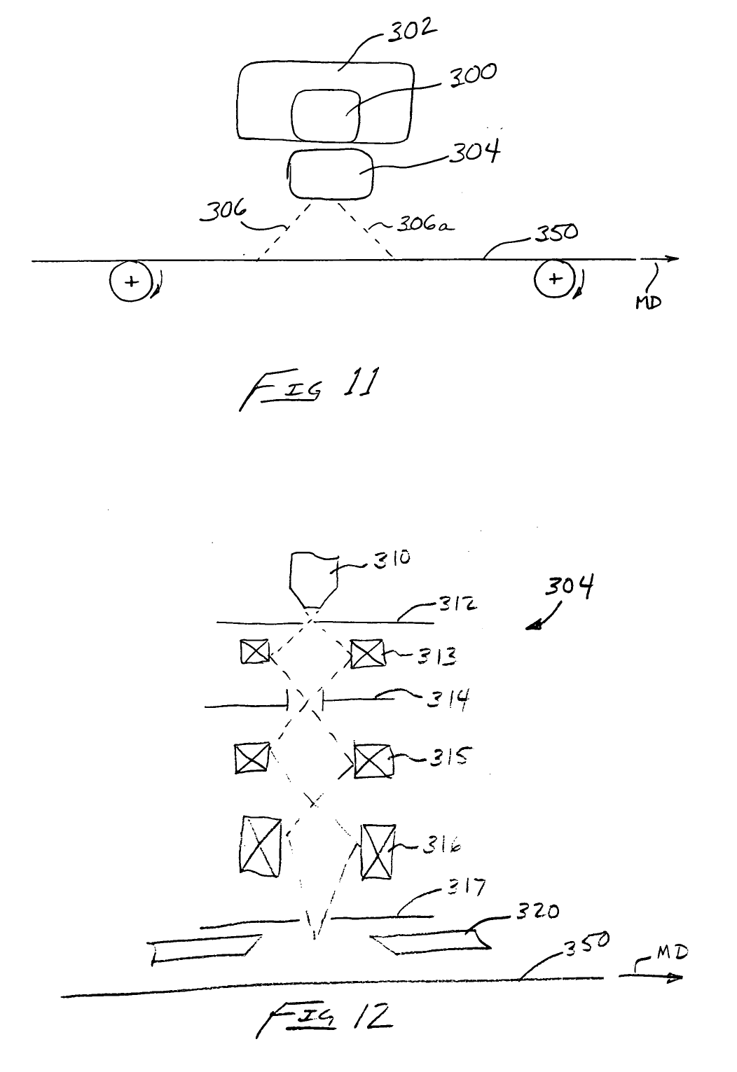

FIG. 10 is a schematic illustration of one suggested embodiment of either the mask pattern of belt 220 or the resulting radiation treated zones of web 210 after radiation treatment, with the region within the dotted outline representing either the belt 220 or web 210, respectively. As a mask pattern, the portions called out as 230 and 240 represent openings, or cut outs, of belt 220, and the dotted outline surrounding these cut outs represents one repeating pattern. As the zoned radiation treated web 210, zone 230 represents a portion treated as a side panel, or “ear” portion on a disposable diaper. Zone 240 represents a portion treated as a leg cuff portion of a disposable diaper. Of course, the number and configuration of zoned portions is infinitely variable, and can be varied simply be varying the predetermined pattern of openings in belt 220.

Another method for producing zones of selectively treated elasticized material is shown in FIG. 11. In this method principles of e-beam lithography are incorporated into the web production process. An e-beam source 300 generates e-beams in a vacuum chamber 302, and an e-beam patterning means 304 shapes, directs, and/or focuses the e-beam by lithographic methods known in the art to pattern the e-beams impinging on web 350. For example, shaping may be effected via a shaping aperture of predetermined dimensions, and directing and focusing can be effected via lenses and masks in a pattern created on a CAD (Computer Aided Design) system, or via conventional magnetic field inducing conducting plates. EBMT (Electron Beam Magnetic Tape)-format lithography data can be obtained through the pattern creation processes from the CAD data with a computer designed for the task. Based on the lithography data, an electron beam exposure apparatus emits a beam of electrons, with or without a mask blank.

FIG. 12 schematically illustrates one e-beam lithographic system suitable for making complex or very fine patterns of radiated zones of the present invention. Electrons generated at an electron gun 310 pass through an anode 312, at least one condenser lens 313, blanking electrode 314, second condenser lens 315 if necessary, object lens (X-Y, blanking electrode) 316, and aperture 317 in sequence, and collide with web 350. Electrons produced by electron gun 81 are controlled by the suitable control circuits as known in the art. The belt 350 speed is one factor that can be varied to ensure the desired pattern exposure is reached.

One benefit of the improvement of the present invention is that the un-crosslinked zones of radiation crosslinked components of a disposable absorbent article remain thermoplastic and can be readily attached to other thermoplastic components by thermal bonding means known in the art. For example, a side panel of a disposable diaper can be thermally bonded by heat seaming to the chassis of the diaper by methods known in the art, without modification to existing production processes. By masking the portion of the side panel to be heat seamed from radiation, the remaining portion of the side panel can be made more elastomeric and lotion resistant, but a diaper utilizing the treated side panel can still be produced on existing production equipment.

Another benefit of the present invention is the production of elastic materials having differing levels of elastic performance in different zones within the same web. By selectively radiation treating discrete zones of the web, each zone can be treated for a relatively shorter or longer time, thereby imparting different material characteristics to the treated zones. Therefore, in a disposable diaper, for example, the side panel portion can have differing elastic characteristics than the waistband portion. And the side panel portion can have zones of varying elastic performance itself, thereby providing for improved wearer comfort due to the distribution of forces within the side panel.

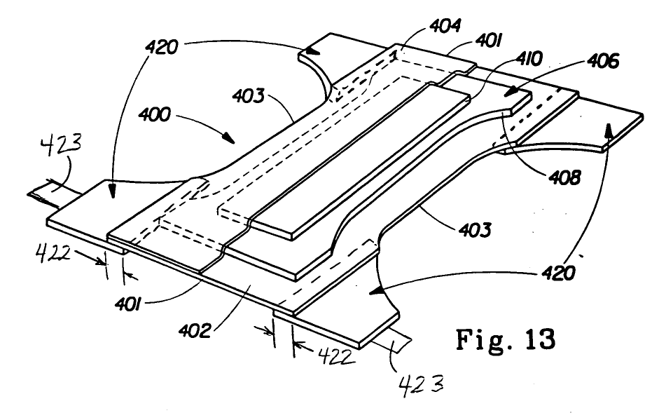

A representative embodiment of an elastomeric web of the present invention utilized in a disposable absorbent article in the form of a diaper 400, is shown in FIG. 13. As used herein, the term “diaper” refers to a garment generally worn by infants and incontinent persons that is worn about the lower torso of the wearer. It should be understood, however, that the elastomeric web of the present invention is also applicable to other absorbent articles such as incontinent briefs, training pants, sanitary napkins, and the like. The diaper 400 depicted in FIG. 13 is a simplified absorbent article that could represent a diaper prior to its being placed on a wearer. It should be understood, however, that the present invention is not limited to the particular type or configuration of diaper shown in FIG. 13. A particularly preferred representative embodiment of a disposable absorbent article in the form of a diaper is taught in U.S. Pat. No. 5,151,092, to Buell et al., issued Sep. 29, 1992, being hereby incorporated herein by reference.

FIG. 13 is a perspective view of the diaper 400 in its uncontracted state (i.e., with all the elastic induced contraction removed) with portions of the structure being cut-away to more clearly show the construction of the diaper 400. The portion of the diaper 400 which contacts the wearer faces the viewer. The diaper 400 is shown in FIG. 13 to preferably comprise a liquid pervious topsheet 404; a liquid impervious backsheet 402 joined with the topsheet 404; and an absorbent core 406 positioned between the topsheet 404 and the backsheet 402. Additional structural features such as elastic leg cuff members and fastening means for securing the diaper in place upon a wearer may also be included.

While the topsheet 404, the backsheet 402, and the absorbent core 406 can be assembled in a variety of well known configurations, a preferred diaper configuration is described generally in U.S. Pat. No. 3,860,003 to Buell, issued Jan. 14, 1975, the disclosure of which is incorporated by reference. Alternatively preferred configurations for disposable diapers herein are also disclosed in U.S. Pat. No. 4,808,178 to Aziz et al., issued Feb. 28, 1989; U.S. Pat. No. 4,695,278 to Lawson, issued Sep. 22, 1987; and U.S. Pat. No. 4,816,025 to Foreman, issued Mar. 28, 1989, the disclosures of each of these patents hereby being incorporated herein by reference.

FIG. 13 shows a representative embodiment of the diaper 400 in which the topsheet 404 and the backsheet 402 are co-extensive and have length and width dimensions generally larger than those of the absorbent core 406. The topsheet 404 is joined with and superimposed on the backsheet 402 thereby forming the periphery of the diaper 400. The periphery defines the outer perimeter or the edges of the diaper 400. The periphery comprises the end edges 401 and the longitudinal edges 403.

The size of the backsheet 402 is dictated by the size of the absorbent core 406 and the exact diaper design selected. In a preferred embodiment, the backsheet 402 has a modified hourglass-shape extending beyond the absorbent core 406 a minimum distance of at least about 1.3 centimeters to about 2.5 centimeters (about 0.5 to about 1.0 inch) around the entire diaper periphery.

The topsheet 404 and the backsheet 402 are joined together in any suitable manner. As used herein, the term “joined” encompasses configurations whereby the topsheet 404 is directly joined to the backsheet 402 by affixing the topsheet 404 directly to the backsheet 402, and configurations whereby the topsheet 404 is indirectly joined to the backsheet 402 by affixing the topsheet 404 to intermediate members which in turn are affixed to the backsheet 402. In a preferred embodiment, the topsheet 404 and the backsheet 402 are affixed directly to each other in the diaper periphery by attachment means (not shown) such as an adhesive or any other attachment means as known in the art. For example, a uniform continuous layer of adhesive, a patterned layer of adhesive, or an array of separate lines or spots of adhesive can be used to affix the topsheet 404 to the backsheet 402.

End edges 401 form a waist region, which in a preferred embodiment comprise a pair of elastomeric side panels 420, which extend laterally from end edges 401 of diaper 400 in an extended configuration. In a preferred embodiment elastomeric side panels 420 comprise the zoned radiation treated portions of an elastomeric web of the present invention. In an especially preferred embodiment, when used as elastomeric side panels, the web of the present invention is further processed to form a composite laminate by bonding it on one, or preferably both sides thereof, with fibrous nonwoven materials to form a soft, compliant elasticized member, utilizing methods known in the art, such as adhesive bonding.

Fibrous nonwoven materials suitable for use in a composite laminate of the present invention include nonwoven webs formed of synthetic fibers (such as polypropylene, polyester, or polyethylene), natural fibers (such as wood, cotton, or rayon), or combinations of natural and synthetic fibers. Suitable nonwoven materials can be formed by various processes such as carding, spun-bonding, hydro-entangling, and other processes familiar to those knowledgeable in the art of nonwovens. A presently preferred fibrous nonwoven material is carded polypropylene, commercially available from Fiberweb of Simpsonville, S.C.

Fibrous nonwoven materials may be bonded to the elastomeric web by any one of various bonding methods known in the art. Suitable bonding methods include adhesive bonding such as by a uniform continuous layer of adhesive, a patterned layer of adhesive, or an array of separate lines, spirals, or spots of adhesive, or other methods such as heat bonds, pressure bonds, ultrasonic bonds, dynamic mechanical bonds, or any other suitable attachment means or combinations of these attachment means as are known in the art. Representative bonding methods are also described in PCT application WO 93/09741, entitled “Absorbent Article Having a Nonwoven and Apertured Film Coversheet”, published May 27, 1993 naming Aziz et al. as inventors, and being hereby incorporated herein by reference.

After bonding to a fibrous nonwoven material, the composite web may tend to be less elastomeric due to the relative inelasticity of the bonded nonwoven. To render the nonwoven more elastic, and to restore elasticity to the composite laminate, the composite web may be processed by methods and apparatus used for elasticizing “zero strain” laminates by incremental stretching, as disclosed in the aforementioned Buell et al. '092 patent, as well as the aforementioned Weber et al. '897, Buell et al. '793, and Weber et al. '679 patents. The resulting elasticized “zero-strain” composite web then has a soft, cloth-like feel for extended use and comfortable fit in an absorbent garment. Side panels 420 may be joined to the diaper in any suitable manner known in the art. For example, as shown in FIG. 13, side panels 420 may be affixed directly to the backsheet 402 by attachment means (not shown) such as an adhesive, thermal bond, or any other attachment means as known in the art. In one embodiment, side panels 420 are thermally bonded by methods known in the art along a heat seam that has relatively low, or no radiation treatment, thereby remaining at least partially, and preferably largely un-crosslinked and thermoplastic. Thus, one benefit of the present invention, is that a portion, or zone, of the side panel 420 can be radiation treated and crosslinked, while a separate portion, or zone, designated generally as 422, can remain largely un-crosslinked, with both zones being optimized with respect to levels of radiation crosslinking for their given function. The side panels 422 may otherwise be constructed in any suitable configuration. Examples of diapers with elasticized side panels are disclosed in U.S. Pat. No. 4,857,067, entitled “Disposable Diaper Having Shirred Ears” issued to Wood, et al. on Aug. 15, 1989; U.S. Pat. No. 4,381,781 issued to Sciaraffa, et al. on May 3, 1983; U.S. Pat. No. 4,938,753 issued to Van Gompel, et al. on Jul. 3, 1990; U.S. Pat. No. 5,151,092 issued to Buell on Sep. 9, 1992; and U.S. Pat. No. 5,221,274 issued to Buell on Jun. 22, 1993; U.S. Pat. No. 5,669,897 issued to La Von, et al. on Sep. 23, 1997 entitled “Absorbent Articles Providing Sustained Dynamic Fit”; U.S. Pat. No. 6,004,306 entitled “Absorbent Article With Multi-Directional Extensible Side Panels” issued to Robles et al. on Dec. 21, 1999; each of which is incorporated herein by reference.

Tape fasteners, e.g., tape tab 423, can be applied to at least one pair of elastomeric side panels 420 to provide a fastening means for holding the diaper on the wearer. The tape tab fasteners can be any of those well known in the art, such as the fastening tape disclosed in the aforementioned Buell '092 patent, and U.S. Pat. No. 3,848,594 to Buell, issued Nov. 19, 1974, the disclosure of which is hereby incorporated by reference. Likewise, mechanical fasteners such as “hook and loop” fasteners can be used, such fasteners being configured by methods known in the art.

Other elastic members (not shown), can be disposed adjacent the periphery of the diaper 400. Elastic members are preferably along each longitudinal edge 403, so that the elastic members tend to draw and hold the diaper 400 against the legs of the wearer. In addition, the elastic members can be disposed adjacent either or both of the end edges 401 of the diaper 400 to provide a waistband as well as or rather than leg cuffs. For example, a suitable waistband is disclosed in U.S. Pat. No. 4,515,595 to Kievit et al., issued May 7, 1985, the disclosure of which is hereby incorporated by reference. In addition, a method and apparatus suitable for manufacturing a disposable diaper having elastically contractible elastic members is described in U.S. Pat. No. 4,081,301 to Buell, issued Mar. 28, 1978, the disclosure of which is hereby incorporated herein by reference.

The elastic members are secured to the diaper 400 in an elastically contractible condition so that in a normally unrestrained configuration, the elastic members effectively contract or gather the diaper 400. The elastic members can be secured in an elastically contractible condition in at least two ways. For example, the elastic members can be stretched and secured while the diaper 400 is in an uncontracted condition. In addition, the diaper 400 can be contracted, for example, by pleating, and the elastic members secured and connected to the diaper 400 while the elastic members are in their relaxed or unstretched condition. The elastic members may extend along a portion of the length of the diaper 400. Alternatively, the elastic members can extend the entire length of the diaper 400, or any other length suitable to provide an elastically contractible line. The length of the elastic members is dictated by the diaper design.

As shown in FIG. 13, the absorbent core 406 preferably includes a fluid distribution member 408. In a preferred configuration such as depicted in FIG. 13, the absorbent core 406 preferably further includes an acquisition layer or member 410 in fluid communication with the fluid distribution member 408 and located between the fluid distribution member 408 and the topsheet 404. The acquisition layer or member 410 may be comprised of several different materials including nonwoven or woven webs of synthetic fibers including polyester, polypropylene, or polyethylene, natural fibers including cotton or cellulose, blends of such fibers, or any equivalent materials or combinations of such materials.

In use, the diaper 400 is applied to a wearer by positioning the back waistband region under the wearer's back, and drawing the reminder of the diaper 400 between the wearer's legs so that the front waistband region is positioned across the front of the wearer. The elastomeric side panels are then extended as necessary for comfort and fit, and the tape-tab or other fasteners are then secured preferably to outwardly facing areas of the diaper 400. By having side panels 420 comprising an elastomeric web of the present invention, the diaper may be adapted for differing sizes of children, for example, in a manner providing for close, comfortable fit with breathability.

While a disposable diaper is shown as a preferred embodiment of a garment comprising an elastomeric web of the present invention, this disclosure is not meant to be limiting to disposable diapers. Other disposable garments may also incorporate an elastomeric web of the invention in various parts to give added comfort, fit and breathability. As well, it is contemplated that even durable garments such as undergarments and swimwear may benefit from the durable porous, extensible characteristics of an elastomeric web of the present invention.

A multilayer film 120 of the present invention may be processed (prior to e-beam treatment) using conventional procedures for producing multilayer films on conventional coextruded film-making equipment. In general, polymers can be melt processed into films using either cast or blown film extrusion methods both of which are described in “Plastics Extrusion Technology” 2nd Ed., by Allan A. Griff (Van Nostrand Reinhold—1976), which is hereby incorporated herein by reference. Cast film is extruded through a linear slot die. Generally, the flat web is cooled on a large moving polished metal roll. It quickly cools, and peels off the first roll, passes over one or more auxiliary rolls, then through a set of rubber-coated pull or “haul-off” rolls, and finally to a winder.

In blown film extrusion the melt is extruded upward through a thin annular die opening. This process is also referred to as tubular film extrusion. Air is introduced through the center of the die to inflate the tube and causes it to expand. A moving bubble is thus formed which is held at constant size by control of internal air pressure. The tube of film is cooled by air blown through one or more chill rings surrounding the tube. The tube is next collapsed by drawing it into a flattened frame through a pair of pull rolls and into a winder.

A coextrusion process requires more than one extruder and either a coextrusion feedblock or a multi-manifold die system or combination of the two to achieve the multilayer film structure. U.S. Pat. Nos. 4,152,387 and 4,197,069, issued May 1, 1979 and Apr. 8, 1980, respectively, both to Cloeren, are hereby incorporated herein by reference, disclose the feedblock principle of coextrusion. Multiple extruders are connected to the feedblock which employs moveable flow dividers to proportionally change the geometry of each individual flow channel in direct relation to the volume of polymer passing through said flow channels. The flow channels are designed such that at their point of confluence, the materials flow together at the same flow rate and pressure eliminating interfacial stress and flow instabilities. Once the materials are joined in the feedblock, they flow into a single manifold die as a composite structure. It is important in such processes that the melt viscosities and melt temperatures of the material do not differ too greatly. Otherwise flow instabilities can result in the die leading to poor control of layer thickness distribution in the multilayer film.

An alternative to feedblock coextrusion is a multi-manifold or vane die as disclosed in aforementioned U.S. Pat. Nos. 4,152,387, 4,197,069, as well as U.S. Pat. No. 4,533,308, issued Aug. 6, 1985 to Cloeren, hereby incorporated herein by reference. Whereas in the feedblock system melt streams are brought together outside and prior to entering the die body, in a multi-manifold or vane die each melt stream has its own manifold in the die where the polymers spread independently in their respective manifolds. The melt streams are married near the die exit with each melt stream at full die width. Moveable vanes provide adjustability of the exit of each flow channel in direct proportion to the volume of material flowing through it, allowing the melts to flow together at the same linear flow rate, pressure, and desired width.

Since the melt flow properties and melt temperatures of polymers vary widely, use of a vane die has several advantages. The die lends itself toward thermal isolation characteristics wherein polymers of greatly differing melt temperatures, for example up to 175° F. (80° C.), can be processed together.

Each manifold in a vane die can be designed and tailored to a specific polymer. Thus the flow of each polymer is influenced only by the design of its manifold, and not forces imposed by other polymers. This allows materials with greatly differing melt viscosities to be coextruded into multilayer films. In addition, the vane die also provides the ability to tailor the width of individual manifolds, such that an internal layer can be completely surrounded by the outer layer leaving no exposed edges. The aforementioned patents also disclose the combined use of feedblock systems and vane dies to achieve more complex multilayer structures.

The multilayer films of the present invention may comprise two or more layers, at least one of the layers being elastomeric. It is also contemplated that multiple elastomeric layers may be utilized, each elastomeric layer being joined to one or two skin layers. In a three-layer film, core layer 101 has opposed first and second sides, one side being substantially continuously joined to one side of each outer skin layer 103 prior to the application of applied stress to the web. Three-layer films, like multilayer film 120 shown in FIG. 4, preferably comprise a central elastomeric core 101 that may comprise from about 10 to 90 percent of the total thickness of the film. Outer skin layers 103 are generally, but not necessarily, identical and may comprise from about 5 to 45 percent of the total thickness of the film. Although an elastomeric layer is generally substantially joined to one or two skin layers without the use of adhesives, adhesives or tie layers may be used to promote adherence between the layers. Tie layers, when employed, may each comprise from bout 5 to 10 percent of the total film thickness.

After the multilayer elastomeric film has been coextruded it is preferably fed to a forming structure for aperturing and cooling, thereby producing a macroscopically-expanded, three-dimensional, apertured elastomeric web of the present invention. In general the film may be formed by drawing such film against a forming screen or other forming structure by means of a vacuum and passing an air or water stream over the outwardly posited surface of the film. Such processes are described in the aforementioned Radel et al. patent as well as in U.S. Pat. No. 4,154,240, issued to Lucas et al., both hereby incorporated herein by reference. Forming a three-dimensional elastomeric web may alternatively be accomplished by applying a liquid stream with sufficient force and mass flux to cause the web formation as disclosed in commonly assigned U.S. Pat. No. 4,695,422, issued to Curro et al. and hereby incorporated herein by reference. Alternatively, the film can be formed as described in commonly assigned U.S. Pat. No. 4,552,709 to Koger et al., and hereby incorporated herein by reference. Preferably the elastomeric web is uniformly macroscopically expanded and apertured by the method of supporting the forming structure in a fluid pressure differential zone by a stationary support member as taught by commonly assigned U.S. Pat. Nos. 4,878,825 and 4,741,877, both to Mullane, Jr., and hereby incorporated herein by reference.

Although not shown, the process of the present invention, using a conventional forming screen having a woven wire support structure, would also form a web within the scope of the present invention. The knuckles of a woven wire forming screen would produce a macroscopically-expanded, three-dimensional web having a pattern of undulations in the first surface, the undulations corresponding to the knuckles of the screen. However, the undulations would remain generally in the plane of the first surface, remote from the plane of the second surface. The cross-section of the interconnecting members would remain generally upwardly concave-shaped with the interconnecting sidewalls of the interconnecting members terminating to form secondary apertures substantially in the plane of the second surface.

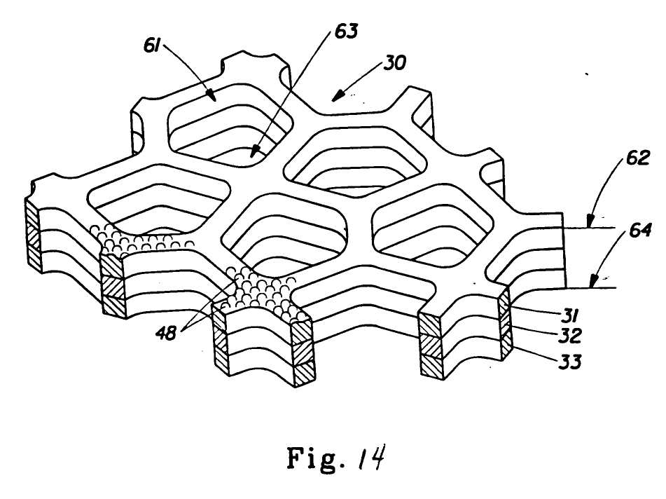

A particularly preferred forming structure comprises a photoetched laminate structure as shown in FIG. 14, showing an enlarged, partially segmented, perspective illustration of a photoetched laminate structure of the type used to form plastic webs of the type generally illustrated in FIG. 2. The laminate structure 30 is preferably constructed generally in accordance with the teachings of the aforementioned Radel et al. patent, and is comprised of individual lamina 31, 32, and 33. A comparison of FIG. 3 with the elastomeric web 80 shown in FIG. 2 reveals the correspondence of primary aperture 71 in plane 102 of the elastomeric web 80 to opening 61 in the uppermost plane 62 of the photoetched laminate structure 30. Likewise, aperture opening 72 in plane 106 of elastomeric web 80 corresponds to opening 63 in lowermost plane 64 of photoetched laminate structure 30.

The uppermost surface of photoetched laminate structure 30 located in uppermost plane 62 may be provided with a microscopic pattern of protuberances 48 without departing from the scope of the present invention. This is preferably accomplished by applying a resist coating which corresponds to the desired microscopic pattern of surface aberrations to the top side of a planar photoetched lamina 31, and thereafter initiating a second photoetching process. The second photoetching process produces a lamina 31 having a microscopic pattern of protuberances 48 on the uppermost surface of the interconnected elements defining the pentagonally shaped apertures, e.g., aperture 41. The microscopic pattern of protuberances does not substantially remove the first surface from the plane of the first surface. The first surface is perceived on a macroscopic scale, while the protuberances are perceived on a microscopic scale. Construction of a laminate structure employing such a pattern of protuberance 48 on its uppermost layer is generally disclosed in the aforementioned Ahr et al. patent.

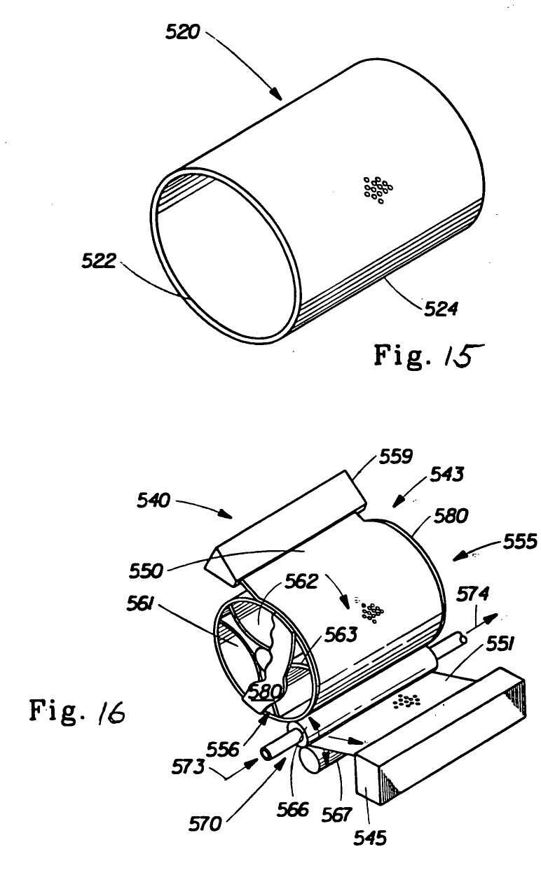

Processes for constructing laminate structures of the type generally disclosed in FIG. 2 are disclosed in the aforementioned Radel et al. patent. The photoetched laminate structures are preferably rolled by conventional techniques into a tubular forming member 520, as illustrated generally in FIG. 15 and their opposing ends joined generally in accordance with the teachings of Radel et al. to produce a seamless tubular forming member 520.

The outermost surface 524 of the tubular forming member 520 is utilized to form the multilayer elastomeric web brought in contact therewith while the innermost surface 522 of the tubular member generally does not contact the plastic web during the forming operation. The tubular member may, in a preferred embodiment of the present invention, be employed as the forming surface on debossing/perforating cylinder 555 in a process of the type described in detail in the aforementioned Lucas et al. patent. A particularly preferred apparatus 540 of the type disclosed in said patent is schematically shown in FIG. 16. It includes debossing and perforating means 543, and constant tension film forwarding and winding means 545 which may, if desired, be substantially identical to and function substantially identically to the corresponding portions of the apparatus shown and described in U.S. Pat. No. 3,674,221 issued to Riemersma on Jul. 4, 1972 and which is hereby incorporated herein by reference. The frame, bearing, supports and the like which must necessarily be provided with respect to the functional members of apparatus 540 are not shown or described in detail in order to simplify and more clearly depict and disclose the present invention, it being understood that such details would be obvious to persons of ordinary skill in the art of designing plastic film converting machinery.

Briefly, apparatus 540, schematically shown in FIG. 16, comprises means for continuously receiving a ribbon of thermoplastic film 550 from coextruder 559, for example, and converting it into a debossed and perforated film 551. Film 550 is preferably supplied directly from the coextrusion process while still above its thermoplastic temperature so as to be vacuumed formed prior to cooling. Alternatively, film 550 may be heated by directing hot air jets against one surface of the film while applying vacuum adjacent the opposite surface of the film. To maintain sufficient control of film 550 to substantially obviate wrinkling and/or macroscopically distending the film, apparatus 540 comprises means for maintaining constant machine direction tension in the film both upstream and downstream of a zone where the temperature is greater than the thermoplastic temperature of the film, but in which zone there is substantially zero machine direction and cross-machine direction tension tending to macroscopically distend the film. The tension is required to control and smooth a running ribbon of thermoplastic film; the zero tension zone results from the film in the zone being at a sufficiently high temperature to enable debossing and perforating the film.

As can be seen in FIG. 16, the debossing and perforating means 543 includes a rotatably mounted debossing perforating cylinder 555 having closed ends 580, a nonrotating triplex vacuum manifold assembly 556 and optional hot air jet means (not shown). The triplex vacuum manifold assembly 556 comprises three manifolds designated 561, 562, and 563. Also shown in FIG. 16 is a power rotated lead-off/chill roll 566 and a soft-face (e.g., low density neoprene) roll 567 which is driven with the chill roll. Briefly, by providing means (not shown) for independently controlling the degree of vacuum in the three vacuum manifolds, a thermoplastic ribbon of film running circumferentially about a portion of the debossing-perforating cylinder 555 is sequentially subjected to a first level of vacuum by manifold 561, a second level of vacuum by manifold 562, and a third level of vacuum by manifold 563. As will be described more fully hereinafter, the vacuum applied to the film by manifold 561 enables maintaining upstream tension in the film, vacuum applied by manifold 562 enables perforating the film, and vacuum applied by manifold 563 enables cooling the film to below its thermoplastic temperature and enables establishing downstream tension therein. If desired, the film contacting surface of the debossing-perforating cylinder 555 may be preheated prior to reaching vacuum manifold 562 by means well known in the art (and therefore not shown) to facilitate better conformance of plastic films comprised of flow-resistant polymers during the debossing operation. The nip 570 intermediate chill roll 566 and the soft-face roll 567 is only nominally loaded because high pressure would iron-out the three-dimensional debossments which are formed in the film in the aforementioned manner. However, even nominal pressure in nip 570 helps the vacuum applied by manifold 563 to isolate downstream tension (i.e., roll winding tension) from the debossing-perforating portion of the debossing-perforating cylinder 555, and enables the nip 570 to peel the debossed and perforated film from the debossing-perforating cylinder 555. Moreover, while vacuum drawn ambient air passing through the film into manifold 563 will normally cool the film to below its thermoplastic temperature, the passage of coolant through the chill roll as indicated by arrows 573, 574 in FIG. 16 will enable the apparatus to handle thicker films or be operated at higher speeds.

The debossing and perforating means 543 comprises the rotatably mounted debossing-perforating cylinder 555, means (not shown) for rotating the cylinder 555 at a controlled peripheral velocity, the non-rotating triplex vacuum manifold assembly 556 inside the debossing-perforating cylinder 555, means (not shown) for applying controlled levels of vacuum inside the three vacuum manifolds 561, 562 and 563 comprising the triplex manifold assembly 556, and optional hot air jet means (not shown). The debossing-perforating cylinder 555 may be constructed by generally following the teachings of the aforementioned Lucas et al. patent, but substituting a tubular laminate forming surface of the present invention for the perforated tubular forming surface disclosed therein.

To summarize, the first vacuum manifold 561, and the third vacuum manifold 563 located within the debossing-perforating cylinder 555 enable maintaining substantially constant upstream and downstream tension, respectively, in a running ribbon of film while the intermediate portion of the film adjacent the second vacuum manifold 562 within the debossing-perforating cylinder 555 is subjected to tension vitiating heat and vacuum to effect debossing and perforating of the film.

While a preferred application of the disclosed photoetched laminate structure is in a vacuum film forming operation as generally outlined in the aforementioned commonly assigned patent issued to Lucas et al., it is anticipated that photoetched laminate forming structures of the present invention could be employed with equal facility to directly form a three-dimensional plastic structure of the present invention. Such a procedure would involve applying a heated fluid plastic material, typically a thermoplastic resin, directly to the forming surface applying a sufficiently great pneumatic differential pressure to the heated fluid plastic material to cause said material to conform to the image of the perforate laminate forming surface, allowing the fluid material to solidify, and thereafter removing the three-dimensional plastic structure from the forming surface.

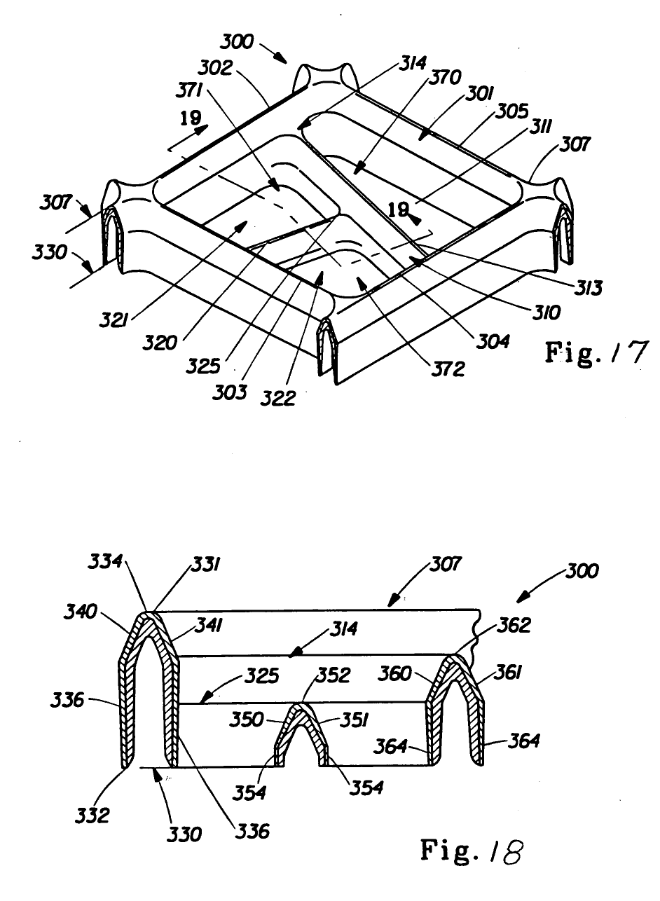

While the web embodiment generally disclosed in FIG. 2 represents a particularly preferred embodiment of the present invention, any number of interconnecting members may be employed within web structures of the present invention, e.g., secondary, tertiary, etc. An example of such a structure is shown in FIG. 17 which also shows a variant of upwardly concave-shaped cross-sections of interconnecting members. The aperture network shown in FIG. 17 comprises a primary aperture 301 formed by a multiplicity of primary interconnecting elements, e.g., elements 302, 303, 304 and 305 interconnected to one another in uppermost plane 307 of the web 300, said opening being further subdivided into smaller secondary apertures 310 and 311 by secondary interconnecting member 313 at an intermediate plane 314. Primary aperture 310 is further subdivided by tertiary interconnecting member 320 into even smaller secondary apertures 321 and 322, respectively, at a still lower plane 325 within web 300. As can be seen from FIG. 18, which is taken along section line 19-19 of FIG. 17, planes 314 and 325 are generally parallel to and located intermediate uppermost plane 307 and lowermost plane 330.

In the web embodiment illustrated in FIGS. 17 and 18, the primary and secondary interconnecting members are further connected to intersecting tertiary interconnecting members, e.g., tertiary interconnecting members 320, which also exhibit a generally upwardly concave-shaped cross-section along their length. The intersecting primary, secondary and tertiary interconnecting members terminate substantially concurrently with one another in the plane 330 of the second surface 332 to form a multiplicity of openings or apertures in the web's second surface, e.g., apertures 370, 371 and 372. It is clear that the interconnected primary, secondary and tertiary interconnecting members located between the first and second surfaces of the web 300 form a closed network connecting each of the primary apertures, e.g., aperture 301 in the first surface 331 of the web, with a multiplicity of secondary apertures, e.g., apertures 370, 371 and 372, in the second surface 332 of the web.

As will be appreciated, the generally upwardly concave-shaped interconnecting members utilized in webs of the present invention may be substantially straight along their entire length. Alternatively, they may be curvilinear, they may comprise two or more substantially straight segments or they may be otherwise oriented in any desired direction along any portion of their length. There is no requirement that the interconnecting members be identical to one another. Furthermore, the aforementioned shapes may be combined in any desired fashion to produce whatever pattern is desired. Regardless of the shape ultimately selected, the upwardly concave-shaped cross-section which exists along the respective lengths of the interconnected interconnecting members helps impart resilience to elastomeric webs of the present invention, as well as three-dimensional standoff.

It will be obvious to those skilled in the art that various changes and modifications can be made without departing from the spirit and scope of the present invention. For example, in the event it is desired to produce webs of the present invention wherein a predetermined portion of the web is capable of preventing fluid transmission, it is feasible to perform the debossing operation without causing rupture of the web in its second surface. Commonly assigned U.S. Pat. No. 4,395,215 issued to Bishop on Jul. 26, 1983 and commonly assigned U.S. Pat. No. 4,747,991 issued to Bishop on May 31, 1988, each of which are hereby incorporated herein by reference, fully disclose how to construct tubular forming structures which are capable of producing three-dimensionally expanded films which are uniformly debossed, but apertured only in predetermined areas.

The disclosures of all patents, patent applications (and any patents which issue thereon, as well as any corresponding published foreign patent applications), and publications mentioned throughout this description are hereby incorporated by reference herein. It is expressly not admitted, however, that any of the documents incorporated by reference herein teach or disclose the present invention.

While particular embodiments of the present invention have been illustrated and described, it would be obvious to those skilled in the art that various other changes and modifications can be made without departing from the spirit and scope of the invention. It is therefore intended to cover in the appended claims all such changes and modifications that are within the scope of this invention.

What is claimed is:

1. An article to be worn adjacent to a person's body, said article comprising an apertured elastomeric web comprising an elastomeric layer having opposed first and second surfaces and two skin layers, each skin layer being substantially continuously joined to one of said opposed surfaces of the elastomeric layer; said web further comprising at least one first region which is radiation crosslinked to modify the elasticity of said first region and at least one second region which is un-crosslinked and wherein said apertured elastomeric web comprises at least a portion of the article that is selected from the group consisting of a side panel, leg cuff, topsheet, backsheet, or combinations thereof.

2. The article of claim 1 wherein said first region has substantially different elastomeric properties than said second region.

3. The article of claim 1 wherein said first region corresponds to a predetermined pattern.

4. The article of claim 1 wherein said article is selected from the group consisting of a pull-on diaper, a training pant, a disposable diaper with fasteners, a feminine napkin, a pantiliner, and an incontinence garment.

5. The article of claim 1 wherein the elastomeric layer comprises from about 20% to about 95% of the total thickness of the web and each skin layer comprises from about 1% to about 50% of the total thickness of the web.

6. The article of claim 1 wherein the elastomeric layer is from about 0.5 mil to about 20 mils thick and each skin layer is from about 0.05 mil to about 5 mils thick.

7. The article of claim 1 wherein the elastomeric layer comprises:
a) from about 20 to about 80 wt % of an elastomeric block copolymer having at least one polyvinylarene block and at least one polyolefin block;
b) from about 3 to about 60 wt % of at least one vinylarene resin; and
c) from about 5 to abut 60 wt % of a processing oil.

8. The article of claim 7 wherein the elastomeric block copolymer is selected from the group consisting of A-B-A triblock copolymers, A-B-A-B tetrablock copolymers, A-B-A-B-A pentablock copolymers, and mixtures thereof, A being a hard block and comprises from about 10% to about 80% of the total weight of the copolymer and B being a soft block and comprises from about 20% to about 90% of the total weight of the copolymer.

9. The article of claim 1 wherein said skin layers comprise a thermoplastic polymer independently selected from the group consisting of polystyrene, poly(a-methyl styrene), polyphenylene oxide, polyolefin, ethylene copolymers, polyamides, polyesters, polyurethanes, and mixtures thereof.

10. A method for making an elastomeric web comprising at least one first region being characterized by a relatively high level of crosslinking and at least one second region being characterized by a relatively low level of crosslinking, the method comprising the steps of:
a) providing a polymeric web;
b) providing an electron beam generator;
c) providing a mask;
d) placing said mask adjacent said polymeric web in a predetermined position; and
e) emitting electrons in a beam from said electron beam generator toward said polymeric web to crosslink said polymeric web until said web reaches a predetermined level of crosslinking.

11. The method of claim 10 wherein said mask comprises an endless belt having cut-outs therein.

12. The method of claim 10 wherein said electrons are directed and focused by a series of electromagnetic components.

13. An apparatus for making an elastomeric web comprising at least one first region being characterized by a relatively high level of crosslinking and at least one second region being characterized by a relatively low level of crosslinking, the apparatus comprising:
a) conveying means for moving a continuous web of material in a machine direction;
b) an electron gun disposed in operative disposition to said web such that emitted electrons are projected toward and onto said web of material;
c) a mask to prevent electrons from impinging on said web of material in a predetermined pattern.
